(19) United States
(12) Patent Application Publication
(10) Pub. No.: US 2026/0314196 A1
(43) Pub. Date: Oct. 8, 2026

(54) Display Device And Electronic Device

(71) Applicant: Samsung Display Co., Ltd., Yongin-si (KR)

(72) Inventors: Eun Jeong Jeon, Yongin-si (KR); Jeong Min Ban, Yongin-si (KR); Dae Geun Lee, Yongin-si (KR)

(73) Assignee: Samsung Display Co., Ltd., Yongin-si (KR)

(21) Appl. No.: 19/450,955

(22) Filed: Jan. 16, 2026

(30) Foreign Application Priority Data
Apr. 3, 2025 (KR) 10-2025-0043469

(51) Int. Cl. H10K 59/131; H10K 59/88

(52) U.S. Cl. CPC H10K 59/131; H10K 59/88

(57) ABSTRACT

Provided are a display device and an electronic device in which a contact state between a pad of a display panel and a terminal of a display driver can be easily detected. The display device includes: a display panel including a first circuit area and a first non-circuit area; a pad located in the first circuit area of the display panel; a display driver connected to the display panel and including a second circuit area and a second non-circuit area; a terminal located in the second circuit area of the display driver and connected to the pad; and a dummy terminal located in the second non-circuit area of the display driver and overlapping the first non-circuit area.

### CROSS REFERENCE TO RELATED APPLICATIONS

This application claims the benefit of Korean Patent Application No. 10-2025-0043469, filed on Apr. 3, 2025, in the Korean Intellectual Property Office, the disclosure of which is incorporated herein in its entirety by reference.

### BACKGROUND

The present disclosure relates to a display device, and more particularly, to a display device and an electronic device in which a contact state between a pad of a display panel and a terminal of a display driver can be easily detected.

Display devices are becoming increasingly important with the development of multimedia. Accordingly, various display devices such as liquid crystal display devices and organic light emitting display devices are being developed.

### SUMMARY

Aspects of the present disclosure provide a display device and an electronic device in which a contact state between a pad of a display panel and a terminal of a display driver can be easily detected.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including: a display panel including a first circuit area and a first non-circuit area; a pad located in the first circuit area of the display panel; a display driver connected to the display panel and including a second circuit area and a second non-circuit area; a terminal located in the second circuit area of the display driver and connected to the pad; and a dummy terminal located in the second non-circuit area of the display driver and overlapping the first non-circuit area.

According to another aspect of the present disclosure, there is provided an electronic device including a display device which provides a display screen, wherein the display device includes: a display panel including a first circuit area and a first non-circuit area; a pad located in the first circuit area of the display panel; a display driver connected to the display panel and including a second circuit area and a second non-circuit area; a terminal located in the second circuit area of the display driver and connected to the pad; and a dummy terminal located in the second non-circuit area of the display driver and overlapping the first non-circuit area.

According to a display device and an electronic device according to an aspect, a contact state between a pad of a display panel and a terminal of a display driver can be easily detected.

For example, according to an aspect, a non-circuit area in which only insulating layers exist without a circuit pattern is located in a display panel including a semiconductor substrate and a display driver including a semiconductor substrate. Therefore, the shape of a terminal (e.g., a dummy terminal) can be easily photographed through the non-circuit area. Accordingly, a contact state between the terminal and a pad can be easily detected.

The effects of the present disclosure are not limited to the above-described effects and other effects which are not described herein will become apparent to those skilled in the art from the following description.

### BRIEF DESCRIPTION OF THE DRAWINGS

These and/or other aspects will become apparent and more readily appreciated from the following description of the aspects, taken in conjunction with the accompanying drawings in which:

FIG. 1 is an exploded perspective view of a display device according to an aspect;

FIG. 2 is a block diagram of the display device according to the aspect;

FIG. 3 is an equivalent circuit diagram of a first pixel according to an aspect;

FIG. 4 is a layout view of an example of a display panel according to an aspect;

FIG. 5 is a cross-sectional view of an example of the display panel, taken along line I-I′ of FIG. 4;

FIG. 6 is a cross-sectional view of an example of the display panel, taken along line II-II′ of FIG. 4;

FIG. 7 is an enlarged view of area A of FIG. 6;

FIG. 8 is a diagram for explaining a method of testing a bonding state between a display panel and a display driver of a display device according to an aspect;

FIG. 9 is a plan view of an overlap area between a display panel and a display driver of a display device according to an aspect;

FIG. 10 is a plan view of the display device in a first circuit area and a first non-circuit area of FIG. 9;

FIG. 11 is a plan view of the display device in a second circuit area and a second non-circuit area of FIG. 9;

FIG. 12 is a plan view of an overlap area between a display panel and a display driver of a display device according to an aspect;

FIG. 13 is a plan view of the display device in a first circuit area and a first non-circuit area of FIG. 12;

FIG. 14 is a plan view of the display device in a second circuit area and a second non-circuit area of FIG. 12;

FIG. 15 is a plan view of an overlap area between a display panel and a display driver of a display device according to an aspect;

FIG. 16 is a plan view of an overlap area between a display panel and a display driver of a display device according to an aspect;

FIG. 17 is a plan view of an overlap area between a display panel and a display driver of a display device according to an aspect;

FIGS. 18 and 19 are diagrams for explaining a method of forming a first non-circuit area and a second non-circuit area by changing a dummy terminal in a display device according to an aspect;

FIG. 20 is a block diagram of an electronic device according to an aspect; and

FIGS. 21, 22, and 23 are schematic diagrams of electronic devices according to various aspects.

### DETAILED DESCRIPTION

The present disclosure will now be described more fully hereinafter with reference to the accompanying drawings, in which preferred aspects of the disclosure are shown. The disclosure may, however, have different aspects and should not be construed as limited to the aspects set forth herein. Rather, these aspects are provided so that this disclosure will be thorough and complete, and will fully convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more aspects. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various aspects of the present disclosure may be combined partially or totally. As will be clearly appreciated by those skilled in the art, technically various interactions and operations are possible. Various aspects can be practiced individually or in combination.

Hereinafter, specific exemplary aspects will be described with reference to the accompanying drawings.

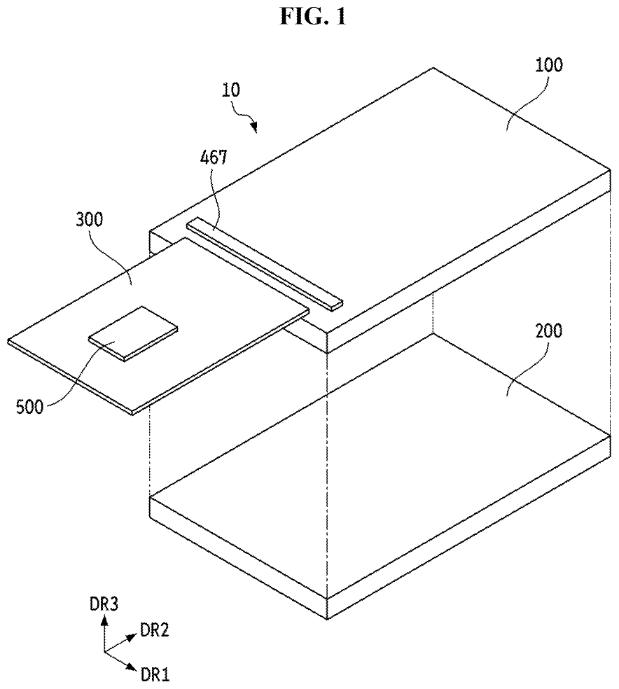

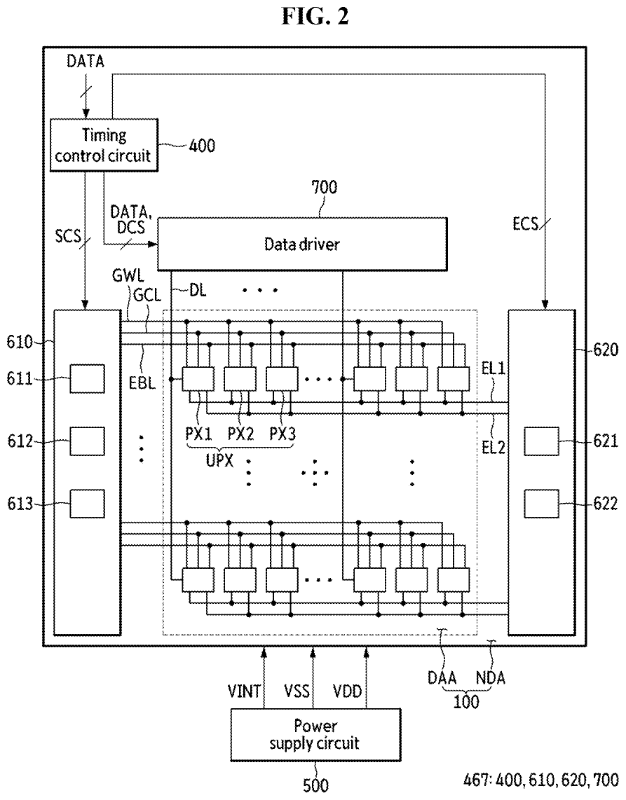

FIG. 1 is an exploded perspective view of a display device 10 according to an aspect. FIG. 2 is a block diagram of the display device 10 according to the aspect.

Referring to FIGS. 1 and 2, the display device 10 according to the aspect is a device for displaying moving images or still images. The display device 10 according to the aspect may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 according to the aspect may be applied as a display unit of a television, a notebook computer, a monitor, a billboard, or an Internet of things (IoT) device. Alternatively, the display device 10 according to the aspect may be applied to smart watches, watch phones, and head-mounted displays (HMDs) for implementing virtual reality and augmented reality.

The display device 10 according to the aspect may include a display panel 100, a display driver 467, a heat dissipation layer 200, a circuit board 300, and a power supply circuit 500.

The display panel 100 may have a planar shape similar to a quadrangle. For example, the display panel 100 may have a planar shape similar to a quadrangle having short sides in a first direction DR1 and long sides in a second direction DR2 intersecting the first direction DR1. In the display panel 100, each corner where a short side extending in the first direction DR1 meets a long side extending in the second direction DR2 may be rounded to have a selected curvature or may be right-angled. The planar shape of the display panel 100 is not limited to a quadrangular shape and may also be similar to other polygonal shapes, a circular shape, or an oval shape. The planar shape of the display device 10 may follow the planar shape of the display panel 100, but aspects of the present specification are not limited to this case.

The display panel 100 may include a display area DAA displaying an image and a non-display area NDA not displaying an image, as illustrated in FIG. 2.

In the display area DAA, a plurality of pixels PX, a plurality of scan lines SL, a plurality of emission control lines EL, and a plurality of data lines DL may be located.

The pixels PX may be arranged in a matrix form in the first direction DR1 and the second direction DR2. The scan lines SL and the emission control lines EL may extend in the first direction DR1 and may be arranged in the second direction DR2. The data lines DL may extend in the second direction DR2 and may be arranged in the first direction DR1.

The scan lines SL may include a plurality of write scan lines GWL, a plurality of control scan lines GCL, and a plurality of bias scan lines EBL. The emission control lines EL may include a plurality of first emission control lines EL1 and a plurality of second emission control lines EL2.

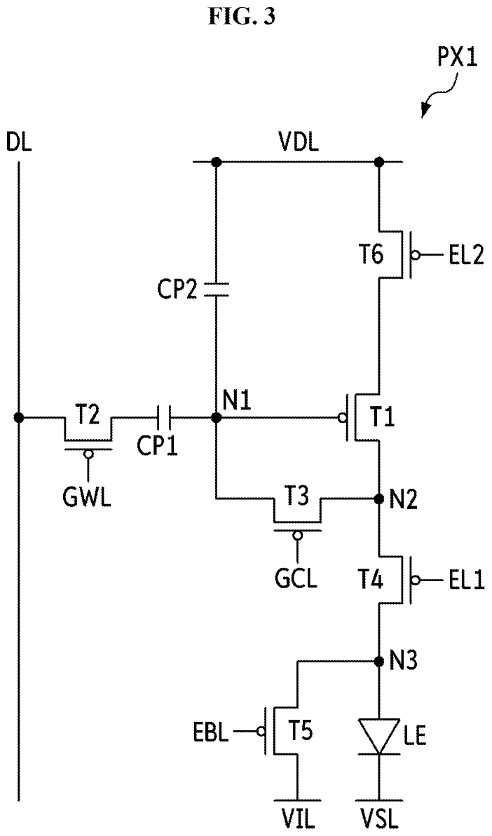

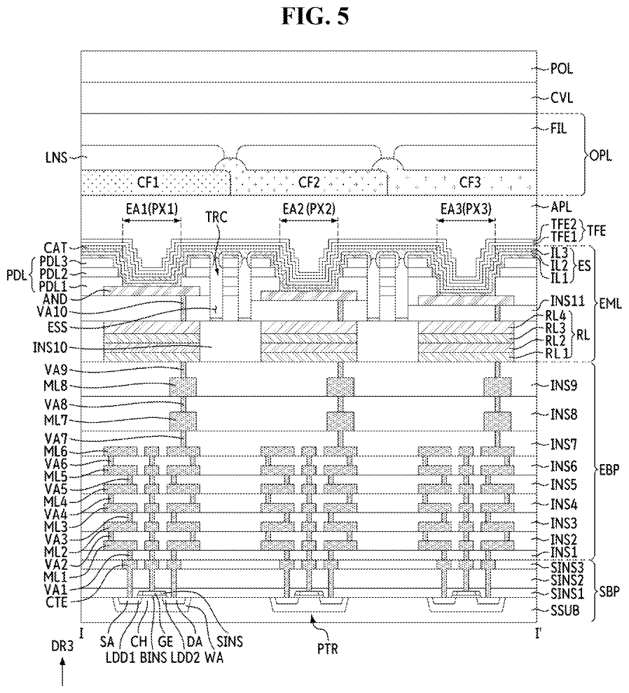

A plurality of unit pixels UPX may include a plurality of pixels PX1 through PX3 located adjacent to each other. The pixels PX1 through PX3 include a plurality of pixel transistors as illustrated in FIG. 3. The pixel transistors may be formed by a semiconductor process and may be located in a semiconductor substrate SSUB (see FIG. 5). For example, the pixel transistors in the display area DAA may be formed as complementary metal oxide semiconductor (CMOS) transistors.

Each of the pixels PX1 through PX3 may be connected to any one of the write scan lines GWL, any one of the control scan lines GCL, any one of the bias scan lines EBL, any one of the first emission control lines EL1, any one of the second emission control lines EL2, and any one of the data lines DL. Each of the pixels PX1 through PX3 may receive a data voltage of a data line DL according to a write scan signal of a write scan line GWL and emit light from a light emitting element according to the data voltage.

The display driver 467 may be located in the non-display area NDA. The display driver 467 may include a timing control circuit 400, a scan driver 610, an emission driver 620, and a data driver 700. For example, the display driver 467 may be a chip (e.g., an integrated circuit (IC) chip including a plurality of transistors manufactured on a wafer) that includes the timing control circuit 400, the scan driver 610, the emission driver 620 and the data driver 700 and can perform each function of the timing control circuit 400, the scan driver 610, the emission driver 620 and the data driver 700.

The scan driver 610 may include a plurality of scan transistors, and the emission driver 620 may include a plurality of emission transistors. The scan transistors and the emission transistors may be formed by a semiconductor process and may be formed in the semiconductor substrate SSUB (see FIG. 5). For example, the scan transistors and the emission transistors may be formed as CMOS transistors.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines EBL.

The emission driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 includes a plurality of data transistors. The data transistors may be formed by a semiconductor process and may be formed in the semiconductor substrate SSUB (see FIG. 5). For example, the data transistors may be formed as CMOS transistors.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, pixels PX1 through PX3 may be selected by a write scan signal of the scan driver 610, and the data voltages may be supplied to the selected pixels PX1 through PX3.

The heat dissipation layer 200 may overlap the display panel 100 in a third direction DR3 which is a thickness direction of the display panel 100. The heat dissipation layer 200 may be located on a surface, e.g., a back surface of the display panel 100. The heat dissipation layer 200 dissipates heat generated from the display panel 100. The heat dissipation layer 130 may include a metal layer having high thermal conductivity, such as graphite, silver (Ag), copper (Cu), or aluminum (Al).

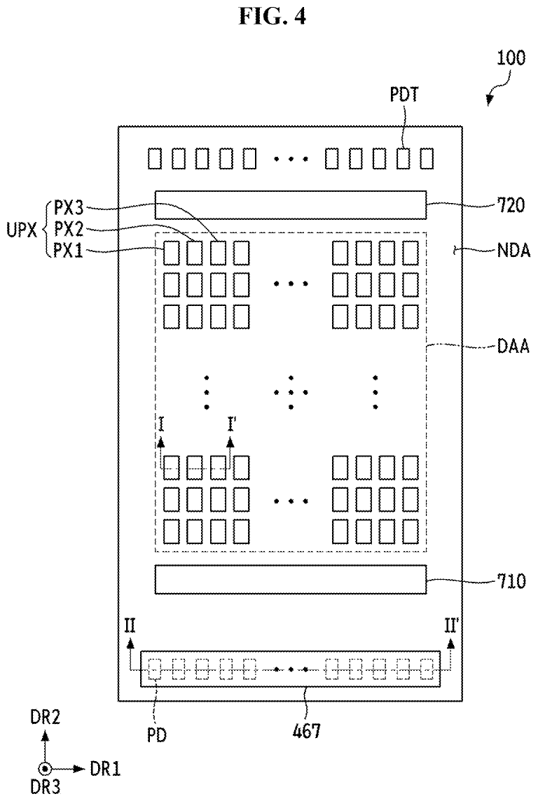

The circuit board 300 may be electrically connected to a plurality of pads (e.g., PD in FIG. 4) of the display panel 100 by using a conductive adhesive member such as an anisotropic conductive film. The circuit board 300 may be a flexible printed circuit board having a flexible material or may be a flexible film. Although the circuit board 300 is unfolded in FIG. 1, it may also be bent. In this case, an end of the circuit board 300 may be placed on the back surface of the display panel 100 and/or a back surface of the heat dissipation layer 200. The end of the circuit board 300 may be an end opposite the other end of the circuit board 300 which is connected to the pads (e.g., PD in FIG. 4) of the display panel 100 by using a conductive adhesive member.

The timing control circuit 400 may receive digital video data and timing signals from the outside. The timing control circuit 400 may generate the scan timing control signal SCS, the emission timing control signal ECS, and the data timing control signal DCS for controlling the display panel 100 according to the timing signals. The timing control circuit 400 may output the scan timing control signal SCS to the scan driver 610 and the emission timing control signal ECS to the emission driver 620. The timing control circuit 400 may output the digital video data and the data timing control signal DCS to the data driver 700.

The power supply circuit 500 may generate a plurality of panel driving voltages according to a power supply voltage received from the outside. For example, the power supply circuit 500 may generate a common voltage VSS, a driving voltage VDD and an initialization voltage VINT and supply them to the display panel 100. The common voltage VSS, the driving voltage VDD, and the initialization voltage VINT will be described later with reference to FIG. 3. The timing control circuit 400 may include a plurality of timing transistors. The timing transistors may be formed by a semiconductor process and may be formed in the semiconductor substrate SSUB (see FIG. 5). For example, the timing transistors may be formed as CMOS transistors.

The power supply circuit 500 may be formed as an integrated circuit and attached to a surface of the circuit board 300. The common voltage VSS, the driving voltage VDD, and the initialization voltage VINT of the power supply circuit 500 may be supplied to the display panel 100 through the circuit board 300.

FIG. 3 is an equivalent circuit diagram of a first pixel PX1 according to an aspect.

Referring to FIG. 3, the first pixel PX1 may be connected to a write scan line GWL, a control scan line GCL, a bias scan line EBL, a first emission control line EL1, a second emission control line EL2, and a data line DL. In addition, the first pixel PX1 may be connected to a common voltage line VSL to which the common voltage VSS corresponding to a low potential voltage is applied, a driving voltage line VDL to which the driving voltage VDD corresponding to a high potential voltage is applied, and an initialization voltage line VIL to which the initialization voltage VINT is applied. Here, the common voltage VSS may be a voltage lower than the initialization voltage VINT. The driving voltage VDD may be a voltage higher than the initialization voltage VINT.

The first pixel PX1 may include a plurality of transistors T1 through T6, a light emitting element LE, a first capacitor CP1, and a second capacitor CP2.

The light emitting element LE emits light according to a driving current Ids flowing through a channel of a first transistor T1. The amount of light emitted from the light emitting element LE may be proportional to the driving current Ids. The light emitting element LE may be located between a fourth transistor T4 and the common voltage line VSL. A first electrode of the light emitting element LE may be connected to a drain electrode of the fourth transistor T4, and a second electrode of the light emitting element LE may be connected to the common voltage line VSL. The first electrode of the light emitting element LE may be an anode, and the second electrode of the light emitting element LE may be a cathode. The light emitting element LE may be an organic light emitting diode including a first electrode, a second electrode, and an organic light emitting layer located between the first electrode and the second electrode. However, aspects of the present specification are not limited to this case. For example, the light emitting element LE may be an inorganic light emitting element including a first electrode, a second electrode, and an inorganic semiconductor located between the first electrode and the second electrode. In this case, the light emitting element LE may be a micro light emitting diode.

The first transistor T1 may be a driving transistor that controls a source-drain current (e.g., a driving current) flowing between a source electrode and a drain electrode according to a voltage applied to a gate electrode. The first transistor T1 includes the gate electrode connected to a first node N1, the source electrode connected to a drain electrode of a sixth transistor T6, and the drain electrode connected to a second node N2.

A second transistor T2 may be located between one electrode of the first capacitor CP1 and the data line DL. The second transistor T2 is turned on by a write scan signal of the write scan line GWL and connects the electrode of the first capacitor CP1 to the data line DL. Accordingly, a data voltage of the data line DL may be applied to the electrode of the first capacitor CP1. The second transistor T2 may include a gate electrode connected to the write scan line GWL, a source electrode connected to the data line DL, and a drain electrode connected to the electrode of the first capacitor CP1.

A third transistor T3 may be located between the first node N1 and the second node N2. The third transistor T3 is turned on by a control scan signal of the control scan line GCL and connects the first node N1 to the second node N2. Accordingly, the gate electrode and source electrode of the first transistor T1 may be connected, and thus the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 is turned on by a first emission control signal of the first emission control line EL1 and connects the second node N2 to the third node N3. Accordingly, the driving current of the first transistor T1 may be supplied to the light emitting element LE. The fourth transistor T4 may include a gate electrode connected to the first emission control line EL1, a source electrode connected to the second node N2, and the drain electrode connected to the third node N3.

A fifth transistor T5 may be located between the third node N3 and the initialization voltage line VIL. The fifth transistor T5 is turned on by a bias scan signal of the bias scan line EBL and connects the third node N3 to the initialization voltage line VIL. Accordingly, the initialization voltage VINT of the initialization voltage line VIL may be applied to the first electrode of the light emitting element LE. The fifth transistor T5 may include a gate electrode connected to the bias scan line EBL, a source electrode connected to the third node N3, and a drain electrode connected to the initialization voltage line VIL.

The sixth transistor T6 may be located between the source electrode of the first transistor T1 and the driving voltage line VDL. The sixth transistor T6 is turned on by a second emission control signal of the second emission control line EL2 and connects the source electrode of the first transistor T1 to the driving voltage line VDL. Accordingly, the driving voltage VDD of the driving voltage line VDL may be applied to the source electrode of the first transistor T1. The sixth transistor T6 may include a gate electrode connected to the second emission control line EL2, a source electrode connected to the driving voltage line VDL, and the drain electrode connected to the source electrode of the first transistor T1.

The first capacitor CP1 is formed between the first node N1 and the drain electrode of the second transistor T2. The first capacitor CP1 may include one electrode connected to the drain electrode of the second transistor T2 and the other electrode connected to the first node N1.

The second capacitor CP2 is formed between the gate electrode of the first transistor T1 and the driving voltage line VDL. The second capacitor CP2 may include one electrode connected to the gate electrode of the first transistor T1 and the other electrode connected to the driving voltage line VDL.

The first node N1 is a contact point between the gate electrode of the first transistor T1, the drain electrode of the third transistor T3, the other electrode of the first capacitor CP1, and the one electrode of the second capacitor CP2. The second node N2 is a contact point between the drain electrode of the first transistor T1, the source electrode of the third transistor T3, and the source electrode of the fourth transistor T4. The third node N3 is a contact point between the drain electrode of the fourth transistor T4, the source electrode of the fifth transistor T5, and the first electrode of the light emitting element LE.

Each of the first through sixth transistors T1 through T6 may be a metal-oxide-semiconductor field effect transistor (MOSFET). For example, each of the first through sixth transistors T1 through T6 may be a P-type MOSFET. However, aspects of the present specification are not limited to this example. Each of the first through sixth transistors T1 through T6 may also be an N-type MOSFET. Alternatively, some of the first through sixth transistors T1 through T6 may be P-type MOSFETs, and the other transistors may be N-type MOSFETs.

In FIG. 3, the first pixel PX1 includes six transistors T1 through T6 and two capacitors CP1 and CP2. However, it should be noted that the equivalent circuit diagram of the first pixel PX1 is not limited to that illustrated in FIG. 3. For example, the number of transistors and the number of capacitors in the first pixel PX1 is not limited to those illustrated in FIG. 3.

In addition, an equivalent circuit diagram of a second pixel PX2 and an equivalent circuit diagram of a third pixel PX3 may be substantially the same as the equivalent circuit diagram of the first pixel PX1 described with reference to FIG. 3. Therefore, the equivalent circuit diagram of the second pixel PX2 and the equivalent circuit diagram of the third pixel PX3 will not be described in the present specification.

FIG. 4 is a layout view of an example of a display panel 100 according to an aspect.

Referring to FIG. 4, a plurality of pixels PX may be arranged in a matrix form in a display area DAA of the display panel 100 according to the aspect. A display driver 467, a first distribution circuit 710, a second distribution circuit 720, a plurality of pads PD, and a plurality of test pads PDT may be arranged in a non-display area NDA of the display panel 100 according to the aspect. As described above, the display driver 467 may include a timing control circuit 400, a scan driver 610, an emission driver 620, and a data driver 700.

The pads PD may be connected to terminals (or pads or bumps) of the display driver 467 through a conductive adhesive member. The pads PD may be located on a third side of the display area DAA. For example, the pads PD may be located on one side of the display area DAA in the second direction DR2. The pads PD may include a material including metal.

The pads PD may be located outside the data driver 700 in the second direction DR2. The pads PD may overlap the data driver 700.

The test pads PDT may be pads for testing whether the display panel 100 operates normally. The test pads PDT may include a material including metal. The test pads PDT may be connected to a jig or a probe pin or to a test circuit board during a test process. The test circuit board may be a printed circuit board including a rigid material or a flexible printed circuit board including a flexible material.

The first distribution circuit 710 may distribute data voltages received through the pads PD to a plurality of data lines DL. For example, the first distribution circuit 710 may distribute data voltages received through the pads PD to P (P is a positive integer of 2 or more) data lines DL. Therefore, the number of pads PD can be reduced. The first distribution circuit 710 may be located on the third side of the display area DAA of the display panel 100. For example, the first distribution circuit 710 may be located on one side of the display area DAA in the second direction DR2. That is, the first distribution circuit 710 may be located on a lower side of the display area DAA.

The second distribution circuit 720 may distribute signals received through the test pads PDT to the scan driver 610, the emission driver 620, and the data lines DL. The test pads PDT and the second distribution circuit 720 may be elements for testing the operation of each of the pixels PX in the display area DAA. The second distribution circuit 720 may be located on a fourth side of the display area DAA of the display panel 100. For example, the second distribution circuit 720 may be located on the other side of the display area DAA in the second direction DR2. That is, the second distribution circuit 720 may be located on an upper side of the display area DAA.

FIG. 5 is a cross-sectional view of an example of the display panel 100, taken along line I-I′ of FIG. 4.

Referring to FIG. 5, the display panel 100 may include a semiconductor backplane SBP, a light emitting element backplane EBP, a display element layer EML, an encapsulation layer TFE, an optical layer OPL, a cover layer CVL, and a polarizing plate POL.

The semiconductor backplane SBP includes a semiconductor substrate SSUB including a plurality of pixel transistors PTR, a plurality of semiconductor insulating layers covering the pixel transistors PTR, and a plurality of contact terminals CTE electrically connected to the pixel transistors PTR. The pixel transistors PTR may be the first through sixth transistors T1 through T6 described with reference to FIG. 3.

The semiconductor substrate SSUB may be a silicon substrate, a germanium substrate, or a silicon-germanium substrate. The semiconductor substrate SSUB may be a substrate doped with a first-type impurity. A plurality of well areas WA may be located in an upper surface of the semiconductor substrate SSUB. The well areas WA may be areas doped with a second-type impurity. The second-type impurity may be different from the first-type impurity described above. For example, when the first-type impurity is a p-type impurity, the second-type impurity may be an n-type impurity. Alternatively, when the first-type impurity is an n-type impurity, the second-type impurity may be a p-type impurity.

Each of the well areas WA includes a source area SA corresponding to a source electrode of a pixel transistor PTR, a drain area DA corresponding to a drain electrode of the pixel transistor PTR, and a channel area CH located between the source area SA and the drain area DA.

A bottom insulating layer BINS may be located between a gate electrode GE and each well area WA. A side insulating layer SINS may be located on side surfaces of the gate electrode GE. The side insulating layer SINS may be located on the bottom insulating layer BINS.

Each of the source area SA and the drain area DA may be an area doped with the first-type impurity. The gate electrode GE of each pixel transistor PTR may overlap a well area WA in the third direction DR3. The channel area CH may overlap the gate electrode GE in the third direction DR3. The source area SA may be located on one side of the gate electrode GE, and the drain area DA may be located on the other side of the gate electrode GE.

Each of the well areas WA further includes a first lightly doped impurity area LDD1 located between the channel area CH and the source area SA and a second lightly doped impurity area LDD2 located between the channel area CH and the drain area DA. The first lightly doped impurity area LDD1 may be an area having a lower impurity concentration than the source area SA due to the bottom insulating layer BINS. The second lightly doped impurity area LDD2 may be an area having a lower impurity concentration than the drain area DA due to the bottom insulating layer BINS. A distance between the source area SA and the drain area DA may be increased by the first lightly doped impurity area LDD1 and the second lightly doped impurity area LDD2. Accordingly, a length of the channel area CH of each pixel transistor PTR may increase, thereby preventing punch-through and hot carrier phenomena caused by a short channel.

A first semiconductor insulating layer SINS1 may be located on the semiconductor substrate SSUB. The first semiconductor insulating layer SINS1 may include a silicon carbon nitride (SiCN) or silicon oxide (SiOₓ)-based inorganic layer, but aspects of the present specification are not limited to this case.

A second semiconductor insulating layer SINS2 may be located on the first semiconductor insulating layer SINS1. The second semiconductor insulating layer SINS2 may include a silicon oxide (SiOₓ)-based inorganic layer, but aspects of the present specification are not limited to this case.

The contact terminals CTE may be located on the second semiconductor insulating layer SINS2. Each of the contact terminals CTE may be connected to any one of the gate electrode GE, the source area SA, and the drain area DA of a pixel transistor PTR through a hole penetrating the first semiconductor insulating layer SINS1 and the second semiconductor insulating layer SINS2. The contact terminals CTE may include any one of copper (Cu), aluminum (Al), tungsten (W), molybdenum (Mo), chromium (Cr), gold (Au), titanium (Ti), nickel (Ni) and neodymium (Nd) or may include an alloy including any one of the same.

A third semiconductor insulating layer SINS3 may be located on side surfaces of each of the contact terminals CTE. An upper surface of each of the contact terminals CTE may be exposed without being covered by the third semiconductor insulating layer SINS3. The third semiconductor insulating layer SINS3 may include a silicon oxide (SiOₓ)-based inorganic layer, but aspects of the present specification are not limited to this case.

The semiconductor substrate SSUB can be replaced with a glass substrate or a polymer resin substrate such as polyimide. In this case, thin-film transistors may be located on the glass substrate or the polymer resin substrate. The glass substrate may be a rigid substrate that is not bent, and the polymer resin substrate may be a flexible substrate that can be bent or curved.

The light emitting element backplane EBP includes a plurality of conductive layers ML1 through ML8, a plurality of via electrodes VA1 through VA9, and a plurality of insulating layers INS1 through INS9. In addition, the light emitting element backplane EBP includes a plurality of insulating layers INS1 through INS9 located between first through eighth conductive layers ML1 through ML8.

The first through eighth conductive layers ML1 through ML8 implement the circuit of the first pixel PX1 illustrated in FIG. 3 by connecting the contact terminals CTE exposed in the semiconductor backplane SBP. For example, the first through sixth transistors T1 through T6 are simply formed in the semiconductor backplane SBP, and the connection of the first through sixth transistors T1 through T6, the first capacitor CP1 and the second capacitor CP2 are achieved through the first through eighth conductive layers ML1 through ML8. In addition, the connection between a drain area corresponding to the drain electrode of the fourth transistor T4, a source area corresponding to the source electrode of the fifth transistor T5, and the first electrode of the light emitting element LE is achieved through the first through eighth conductive layers ML1 through ML8.

A first insulating layer INS1 may be located on the semiconductor backplane SBP. Each of first via electrodes VA1 may penetrate the first insulating layer INS1 and may be connected to a contact terminal CTE exposed in the semiconductor backplane SBP. Each of the first conductive layers ML1 may be located on the first insulating layer INS1 and may be connected to a first via electrode VA1.

A second insulating layer INS2 may be located on the first insulating layer INS1 and the first conductive layers ML1. Each of second via electrodes VA2 may penetrate the second insulating layer INS2 and may be connected to an exposed first conductive layer ML1. Each of the second conductive layers ML2 may be located on the second insulating layer INS2 and may be connected to a second via electrode VA2.

A third insulating layer INS3 may be located on the second insulating layer INS2 and the second conductive layers ML2. Each of third via electrodes VA3 may penetrate the third insulating layer INS3 and may be connected to an exposed second conductive layer ML2. Each of the third conductive layers ML3 may be located on the third insulating layer INS3 and may be connected to a third via electrode VA3.

A fourth insulating layer INS4 may be located on the third insulating layer INS3 and the third conductive layers ML3. Each of fourth via electrodes VA4 may penetrate the fourth insulating layer INS4 and may be connected to an exposed third conductive layer ML3. Each of the fourth conductive layers ML4 may be located on the fourth insulating layer INS4 and may be connected to a fourth via electrode VA4.

A fifth insulating layer INS5 may be located on the fourth insulating layer INS4 and the fourth conductive layers ML4. Each of fifth via electrodes VA5 may penetrate the fifth insulating layer INS5 and may be connected to an exposed fourth conductive layer ML4. Each of the fifth conductive layers ML5 may be located on the fifth insulating layer INS5 and may be connected to a fifth via electrode VA5.

A sixth insulating layer INS6 may be located on the fifth insulating layer INS5 and the fifth conductive layers ML5. Each of sixth via electrodes VA6 may penetrate the sixth insulating layer INS6 and may be connected to an exposed fifth conductive layer ML5. Each of the sixth conductive layers ML6 may be located on the sixth insulating layer INS6 and may be connected to a sixth via electrode VA6.

A seventh insulating layer INS7 may be located on the sixth insulating layer INS6 and the sixth conductive layers ML6. Each of seventh via electrodes VA7 may penetrate the seventh insulating layer INS7 and may be connected to an exposed sixth conductive layer ML6. Each of the seventh conductive layers ML7 may be located on the seventh insulating layer INS7 and may be connected to a seventh via electrode VA7.

An eighth insulating layer INS8 may be located on the seventh insulating layer INS7 and the seventh conductive layers ML7. Each of eighth via electrodes VA8 may penetrate the eighth insulating layer INS8 and may be connected to an exposed seventh conductive layer ML7. Each of the eighth conductive layers ML8 may be located on the eighth insulating layer INS8 and may be connected to an eighth via electrode VA8.

The first through eighth conductive layers ML1 through ML8 and the first through eighth via electrodes VA1 through VA8 may include substantially the same material. The first through eighth conductive layers ML1 through ML8 and the first through eighth via electrodes VA1 through VA8 may include any one of copper (Cu), aluminum (Al), tungsten (W), molybdenum (Mo), chromium (Cr), gold (Au), titanium (Ti), nickel (Ni) and neodymium (Nd) or may include an alloy including any one of the same. The first through eighth via electrodes VA1 through VA8 may include substantially the same material. The first through eighth insulating layers INS1 through INS8 may include a silicon oxide (SiOₓ)-based inorganic layer, but aspects of the present specification are not limited to this case.

A thickness of the first conductive layers ML1, a thickness of the second conductive layers ML2, a thickness of the third conductive layers ML3, a thickness of the fourth conductive layers ML4, a thickness of the fifth conductive layers ML5, and a thickness of the sixth conductive layers ML6 may each be greater than a thickness of the first via electrodes VA1, a thickness of the second via electrodes VA2, a thickness of the third via electrodes VA3, a thickness of the fourth via electrodes VA4, a thickness of the fifth via electrodes VA5, and a thickness of the sixth via electrodes VA6. The thickness of the second conductive layers ML2, the thickness of the third conductive layers ML3, the thickness of the fourth conductive layers ML4, the thickness of the fifth conductive layers ML5, and the thickness of the sixth conductive layers ML6 may each be greater than the thickness of the first conductive layers ML1. The thickness of the second conductive layers ML2, the thickness of the third conductive layers ML3, the thickness of the fourth conductive layers ML4, the thickness of the fifth conductive layers ML5, and the thickness of the sixth conductive layers ML6 may be substantially the same. For example, the thickness of the first conductive layers ML1 may be about 1,360 Å, and the thickness of the second conductive layers ML2, the thickness of the third conductive layers ML3, the thickness of the fourth conductive layers ML4, the thickness of the fifth conductive layers ML5, and the thickness of the sixth conductive layers ML6 may each be about 1,440 Å. In addition, the thickness of the first via electrodes VA1, the thickness of the second via electrodes VA2, the thickness of the third via electrodes VA3, the thickness of the fourth via electrodes VA4, the thickness of the fifth via electrodes VA5, and the thickness of the sixth via electrodes VA6 may each be about 1,150 Å.

A thickness of the seventh conductive layers ML7 and a thickness of the eighth conductive layers ML8 may each be greater than the thickness of the first conductive layers ML1, the thickness of the second conductive layers ML2, the thickness of the third conductive layers ML3, the thickness of the fourth conductive layers ML4, the thickness of the fifth conductive layers ML5, and the thickness of the sixth conductive layer ML6. The thickness of the seventh conductive layers ML7 and the thickness of the eighth conductive layers ML8 may each be greater than a thickness of the seventh via electrodes VA7 and a thickness of the eighth via electrodes VA8. The thickness of the seventh via electrodes VA7 and the thickness of the eighth via electrodes VA8 may each be greater than the thickness of the first via electrodes VA1, the thickness of the second via electrodes VA2, the thickness of the third via electrodes VA3, the thickness of the fourth via electrodes VA4, the thickness of the fifth via electrodes VA5, and the thickness of the sixth via electrodes VA6. The thickness of the seventh conductive layers ML7 and the thickness of the eighth conductive layers ML8 may be substantially the same. For example, the thickness of the seventh conductive layers ML7 and the thickness of the eighth conductive layers ML8 may each be about 9,000 Å. The thickness of the seventh via electrodes VA7 and the thickness of the eighth via electrodes VA8 may each be about 6,000 Å.

A ninth insulating layer INS9 may be located on the eighth insulating layer INS8 and the eighth conductive layers ML8. The ninth insulating layer INS9 may include a silicon oxide (SiOₓ)-based inorganic layer, but aspects of the present specification are not limited to this case.

Each of ninth via electrodes VA9 may penetrate the ninth insulating layer INS9 and may be connected to an exposed eighth conductive layer ML8. The ninth via electrodes VA9 may include any one of copper (Cu), aluminum (Al), tungsten (W), molybdenum (Mo), chromium (Cr), gold (Au), titanium (Ti), nickel (Ni) and neodymium (Nd) or may include an alloy including any one of the same. A thickness of the ninth via electrodes VA9 may be about 16,500 Å.

The display element layer EML may be located on the light emitting element backplane EBP. The display element layer EML may include a reflective electrode layer RL, tenth and eleventh insulating layers INS10 and INS11, tenth via electrodes VA10, light emitting elements LE, each including a first electrode AND, a light emitting stack layer ES and a second electrode CAT, a pixel defining layer PDL, and a plurality of trenches TRC.

The reflective electrode layer RL may be located on the ninth insulating layer INS9. The reflective electrode layer RL may include one or more reflective electrodes RL1 through RL4. For example, the reflective electrode layer RL may include first through fourth reflective electrodes RL1 through RL4 as illustrated in FIG. 5.

Each of the first reflective electrodes RL1 may be located on the ninth insulating layer INS9 and may be connected to a ninth via electrode VA9. The first reflective electrodes RL1 may include any one of copper (Cu), aluminum (Al), tungsten (W), molybdenum (Mo), chromium (Cr), gold (Au), titanium (Ti), nickel (Ni) and neodymium (Nd) or may include an alloy including any one of the same. For example, the first reflective electrodes RL1 may include titanium nitride (TiN).

Each of the second reflective electrodes RL2 may be located on a first reflective electrode RL1. The second reflective electrodes RL2 may include any one of copper (Cu), aluminum (Al), tungsten (W), molybdenum (Mo), chromium (Cr), gold (Au), titanium (Ti), nickel (Ni) and neodymium (Nd) or may include an alloy including any one of the same. For example, the second reflective electrodes RL2 may include aluminum (Al).

Each of the third reflective electrodes RL3 may be located on a second reflective electrode RL2. The third reflective electrodes RL3 may include any one of copper (Cu), aluminum (Al), tungsten (W), molybdenum (Mo), chromium (Cr), gold (Au), titanium (Ti), nickel (Ni) and neodymium (Nd) or may include an alloy including any one of the same. For example, the third reflective electrodes RL3 may include titanium nitride (TiN).

Each of the fourth reflective electrodes RL4 may be located on a third reflective electrode RL3. The fourth reflective electrodes RL4 may include any one of copper (Cu), aluminum (Al), tungsten (W), molybdenum (Mo), chromium (Cr), gold (Au), titanium (Ti), nickel (Ni) and neodymium (Nd) or may include an alloy including any one of the same. For example, the fourth reflective electrodes RL4 may include titanium (Ti).

Since the second reflective electrodes RL2 are electrodes that substantially reflect light from the light emitting elements LE, a thickness of the second reflective electrodes RL2 may be greater than a thickness of the first reflective electrodes RL1, a thickness of the third reflective electrodes RL3, and a thickness of the fourth reflective electrodes RL4. For example, the thickness of the first reflective electrodes RL1, the thickness of the third reflective electrodes RL3 and the thickness of the fourth reflective electrodes RL4 may be about 100 Å, and the thickness of the second reflective electrodes RL2 may be about 850 Å.

The tenth insulating layer INS10 may be located on the ninth insulating layer INS9. The tenth insulating layer INS10 may be located between reflective electrodes RL adjacent to each other in a horizontal direction. The tenth insulating layer INS10 may be located on the reflective electrode layer RL in a third pixel PX3. The tenth insulating layer INS10 may include a silicon oxide (SiOₓ)-based inorganic layer, but aspects of the present specification are not limited to this case.

The eleventh insulating layer INS11 may be located on the tenth insulating layer INS10 and the reflective electrode layer RL. The eleventh insulating layer INS11 may include a silicon oxide (SiOₓ)-based inorganic layer, but aspects of the present specification are not limited to this case. The tenth insulating layer INS10 and the eleventh insulating layer INS11 may be optical auxiliary layers through which light reflected by the reflective electrode layer RL among light emitted from the light emitting elements LE passes.

The tenth insulating layer INS11 may not be located under the first electrode AND of at least any one of a first pixel PX1, a second pixel PX2 and a third pixel PX3, in order to match resonance distances of light emitted from the light emitting elements LE. The first electrode AND of the first pixel PX1 may be directly located on the reflective electrode layer RL. The eleventh insulating layer INS11 may be located under the first electrode AND of the second pixel PX2. The tenth insulating layer INS10 and the eleventh insulating layer INS11 may be located under the first electrode AND of the third pixel PX3.

In summary, a distance between the first electrode AND and the reflective electrode layer RL may be different in each of the first pixel PX1, the second pixel PX2, and the third pixel PX3. That is, the presence or absence of the tenth insulating layer INS10 and the eleventh insulating layer INS11 in each of the first pixel PX1, the second pixel PX2, and the third pixel PX3 may be set in order to adjust the distance from the reflective electrode layer RL to the second electrode CAT according to the main wavelength of light emitted from each of the first pixel PX1, the second pixel PX2, and the third pixel PX3.

The tenth via electrodes VA10 may penetrate the tenth insulating layer INS10 and/or the eleventh insulating layer INS11 in the second pixel PX2 and the third pixel PX3 and may be connected to exposed fourth reflective electrodes RL4, respectively. The tenth via electrodes VA10 may include any one of copper (Cu), aluminum (Al), tungsten (W), molybdenum (Mo), chromium (Cr), gold (Au), titanium (Ti), nickel (Ni) and neodymium (Nd) or may include an alloy including any one of the same. A thickness of a tenth via electrode VA10 in the second pixel PX2 may be greater than a thickness of a tenth via electrode VA10 in the third pixel PX3.

The first electrode AND of each of the light emitting elements LE may be located on the eleventh insulating layer INS11 and may be connected to a tenth via electrode VA10. The first electrode AND of each of the light emitting elements LE may be connected to the drain area DA or the source area SA of a pixel transistor PTR through a tenth via electrode VA10, the first through fourth reflective electrodes RL1 through RL4, the first through ninth via electrodes VA1 through VA9, the first through eighth conductive layers ML1 through ML8, and a contact terminal CTE. The first electrode AND of each of the light emitting elements LE may include any one of copper (Cu), aluminum (Al), tungsten (W), molybdenum (Mo), chromium (Cr), gold (Au), titanium (Ti), nickel (Ni) and neodymium (Nd) or may include an alloy including any one of the same. For example, the first electrode AND of each of the light emitting elements LE may be titanium nitride (TiN).

The pixel defining layer PDL may be located on a portion of the first electrode AND of each of the light emitting elements LE. The pixel defining layer PDL may cover edges of the first electrode AND of each of the light emitting elements LE. The pixel defining layer PDL defines first through third emission areas EA1 through EA3.

The first emission area EA1 may be defined as an area where the first electrode AND, the light emitting stack layer ES, and the second electrode CAT are sequentially stacked to emit light in the first pixel PX1. The second emission area EA2 may be defined as an area where the first electrode AND, the light emitting stack layer ES, and the second electrode CAT are sequentially stacked to emit light in the second pixel PX2. The third emission area EA3 may be defined as an area where the first electrode AND, the light emitting stack layer ES, and the second electrode CAT are sequentially stacked to emit light in the third pixel PX3.

The pixel defining layer PDL may include first through third pixel defining layers PDL1 through PDL3. The first pixel defining layer PDL1 may be located on the edges of the first electrode AND of each of the light emitting elements LE. The second pixel defining layer PDL2 may be located on the first pixel defining layer PDL1. The third pixel defining layer PDL3 may be located on the second pixel defining layer PDL2. The first pixel defining layer PDL1, the second pixel defining layer PDL2, and the third pixel defining layer PDL3 may include a silicon oxide (SiOₓ)-based inorganic layer, but aspects of the present specification are not limited to this case. A thickness of the first pixel defining layer PDL1, a thickness of the second pixel defining layer PDL2, and a thickness of the third pixel defining layer PDL3 may each be about 500 Å.

If the first pixel defining layer PDL1, the second pixel defining layer PDL2, and the third pixel defining layer PDL3 are formed as a single pixel defining layer, a height of the single pixel defining layer may increase, causing a first encapsulating inorganic layer TFE1 to be broken due to step coverage. The step coverage refers to the ratio of the degree of thin-film coating on an inclined portion to the degree of thin-film coating on a flat portion. The lower the step coverage, the higher the possibility that the thin film will be broken on the inclined portion.

Therefore, in order to prevent the first encapsulating inorganic layer TFE1 from being broken due to the step coverage, the first pixel defining layer PDL1, the second pixel defining layer PDL2, and the third pixel defining layer PDL3 may have a step-like cross-sectional structure. For example, a width of the first pixel defining layer PDL1 may be greater than a width of the second pixel defining layer PDL2 and a width of the third pixel defining layer PDL3, and the width of the second pixel defining layer PDL2 may be greater than the width of the third pixel defining layer PDL3. The width of the first pixel defining layer PDL1 refers to a horizontal length of the first pixel defining layer PDL1 defined by the first direction DR1 and the second direction DR2.

Each of the trenches TRC may penetrate the first pixel defining layer PDL1, the second pixel defining layer PDL2, and the third pixel defining layer PDL3. In addition, each of the trenches TRC may penetrate the eleventh insulating layer INS11. In addition, although not illustrated in the drawing, a portion of the tenth insulating layer INS10 may be depressed in each of the trenches TRC.

At least one trench TRC may be located between neighboring pixels PX1 through PX3. Although two trenches TRC are located between the neighboring pixels PX1 through PX3 in FIG. 5, aspects of the present specification are not limited to this case.

The light emitting stack layer ES may include a plurality of stack layers. In FIG. 5, the light emitting stack layer ES has a three-tandem structure including a first stack layer IL1, a second stack layer IL2, and a third stack layer IL3. However, aspects of the present specification are not limited to this case. For example, the light emitting stack layer ES may also have a two-tandem structure including two intermediate layers.

In the three-tandem structure, the light emitting stack layer ES may have a tandem structure including a plurality of stack layers IL1 through IL3 that emit different lights. For example, the light emitting stack layer ES may include the first stack layer IL1 that emits light of a first color, the second stack layer IL2 that emits light of a third color, and the third stack layer IL3 that emits light of a second color. The first stack layer IL1, the second stack layer IL2, and the third stack layer IL3 may be sequentially stacked.

The first stack layer IL1 may have a structure in which a first hole transport layer, a first organic light emitting layer emitting light of the first color, and a first electron transport layer are sequentially stacked. The second stack layer IL2 may have a structure in which a second hole transport layer, a second organic light emitting layer emitting light of the second color, and a second electron transport layer are sequentially stacked. The third stack layer IL3 may have a structure in which a third hole transport layer, a third organic light emitting layer emitting light of the third color, and a third electron transport layer are sequentially stacked.

A first charge generation layer may be located between the first stack layer IL1 and the second stack layer IL2 to supply charges to the second stack layer IL2 and electrons to the first stack layer IL1. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer may be located between the second stack layer IL2 and the third stack layer IL3 to supply charges to the third stack layer IL3 and electrons to the second stack layer IL2. The second charge generation layer may include an N-type charge generation layer that supplies electrons to the second stack layer IL2 and a P-type charge generation layer that supplies holes to the third stack layer IL3.

The first stack layer IL1 may be located on the first electrodes AND and the pixel defining layer PDL and may be located on a bottom surface of each of the trenches TRC. Due to the trenches TRC, the first stack layer IL1 may be broken between neighboring pixels PX1 through PX3. The second stack layer IL2 may be located on the first stack layer IL1. Due to the trenches TRC, the second stack layer IL2 may be broken between the neighboring pixels PX1 through PX3. A hole ESS or an empty space may be located between the first stack layer IL1 and the second stack layer IL2. The third stack layer IL3 may be located on the second stack layer IL2. The third stack layer IL3 may not be broken by the trenches TRC and may cover the second stack layer IL2 in each of the trenches TRC. That is, in the three-tandem structure, each of the trenches TRC may be a structure for interrupting the first and second stack layers IL1 and IL2, the first charge generation layer, and the second charge generation layer of the display element layer EML between the neighboring pixels PX1 through PX3. In addition, in the two-tandem structure, each of the trenches TRC may be a structure for interrupting a charge generation layer located between a lower intermediate layer and an upper intermediate layer and interrupting the lower intermediate layer.

In order to stably interrupt the first and second stack layers IL1 and IL2 of the display element layer EML between the neighboring pixels PX1 through PX3, a height of each of the trenches TRC may be greater than a height of the pixel defining layer PDL. The height of each of the trenches TRC refers to a length of each of the trenches TRC in the third direction DR3. The height of the pixel defining layer PDL refers to a length of the pixel defining layer PDL in the third direction DR3. In order to interrupt the first through third stack layers IL1 through IL3 of the display element layer EML between the neighboring pixels PX1 through PX3, another structure may exist instead of the trenches TRC. For example, instead of the trenches TRC, reverse-tapered barrier ribs may be located on the pixel defining layer PDL.

The number of stack layers IL1 through IL3 emitting different lights is not limited to that illustrated in FIG. 5. For example, the light emitting stack layer ES may include two intermediate layers. In this case, any one of the two intermediate layers may be substantially the same as the first stack layer IL1, and the other may include a second hole transport layer, a second organic light emitting layer, a third organic light emitting layer and a second electron transport layer. In this case, a charge generation layer may be located between the two intermediate layers to supply electrons to any one of the two intermediate layers and to supply charges to the other intermediate layer.

In addition, in FIG. 5, the first through third stack layers IL1 through IL3 are located in all of the first emission area EA1, the second emission area EA2, and the third emission area EA3. However, aspects of the present specification are not limited to this case. For example, the first stack layer IL1 may be located in the first emission area EA1 and may not be located in the second emission area EA2 and the third emission area EA3. In addition, the second stack layer IL2 may be located in the second emission area EA2 and may not be located in the first emission area EA1 and the third emission area EA3. In addition, the third stack layer IL3 may be located in the third emission area EA3 and may not be located in the first emission area EA1 and the second emission area EA2. In this case, first through third color filters CF1 through CF3 of the optical layer OPL may be omitted.

The second electrode CAT may be located on the third stack layer IL3. The second electrode CAT may be located on the third stack layer IL3 in each of the trenches TRC. The second electrode CAT may include a transparent conductive material (TCO) that can transmit light, such as indium tin oxide (ITO) or indium zinc oxide (IZO), or a semi-transmissive conductive material such as magnesium (Mg), silver (Ag) or an alloy of Mg and Ag. When the second electrode CAT includes a semi-transmissive conductive material, the light output efficiency of each of the first through third pixels PX1 through PX3 may be increased by a microcavity.

The encapsulation layer TFE may be located on the display element layer EML. The encapsulation layer TFE may include one or more inorganic layers TFE1 and TFE2 to prevent the penetration of oxygen or moisture into the display element layer EML. For example, the encapsulation layer TFE may include the first encapsulating inorganic layer TFE1 and a second encapsulating inorganic layer TFE2.

The first encapsulating inorganic layer TFE1 may be located on the second electrode CAT. The first encapsulating inorganic layer TFE1 may be a multilayer in which one or more inorganic layers selected from silicon nitride (SiNₓ), silicon oxynitride (SiON), and silicon oxide (SiOₓ) are alternately stacked. The first encapsulating inorganic layer TFE1 may be formed by a chemical vapor deposition (CVD) process.

The second encapsulating inorganic layer TFE2 may be located on the first encapsulating inorganic layer TFE1. The second encapsulating inorganic layer TFE2 may include a titanium oxide (TiOₓ) or aluminum oxide (AlOₓ) layer, but aspects of the present specification are not limited to this case. The second encapsulating inorganic layer TFE2 may be formed by an atomic layer deposition (ALD) process. A thickness of the second encapsulating inorganic layer TFE2 may be smaller than a thickness of the first encapsulating inorganic layer TFE1.

An organic layer APL may be a layer for increasing the interfacial adhesion between the encapsulation layer TFE and the optical layer OPL. The organic layer APL may be an organic layer such as acryl resin, epoxy resin, phenolic resin, polyamide resin, or polyimide resin.

The optical layer OPL includes a plurality of color filters CF1 through CF3, a plurality of lenses LNS, and a filling layer FIL. The color filters CF1 through CF3 may include the first through third color filters CF1 through CF3. The first through third color filters CF1 through CF3 may be located on the organic layer APL.

The first color filter CF1 may overlap the first emission area EA1 of the first pixel PX1. The first color filter CF1 may transmit light of the first color, for example, light in a red wavelength band. The red wavelength band may be about 600 to 750 nm. Therefore, the first color filter CF1 may transmit the light of the first color among the light emitted from the first emission area EA1.

The second color filter CF2 may overlap the second emission area EA2 of the second pixel PX2. The second color filter CF2 may transmit light of the second color, for example, light in a green wavelength band. The green wavelength band may be about 480 to 560 nm. Therefore, the second color filter CF2 may transmit the light of the second color among the light emitted from the second emission area EA2.

The third color filter CF3 may overlap the third emission area EA3 of the third pixel PX3. The third color filter CF3 may transmit light of the third color, that is, light in a blue wavelength band. The blue wavelength band may be about 370 to 460 nm. Therefore, the third color filter CF3 may transmit the light of the third color among the light emitted from the third emission area EA3.

The lenses LNS may be located on the first color filter CF1, the second color filter CF2, and the third color filter CF3, respectively. Each of the lenses LNS may be a structure for increasing the proportion of light directed to the front of the display device 10. Each of the lenses LNS may have an upwardly convex cross-sectional shape.

The filling layer FIL may be located on the lenses LNS. The filling layer FIL may have a selected refractive index so that light can travel in the third direction DR3 at an interface between the lenses LNS and the filling layer FIL. In addition, the filling layer FIL may be a planarization layer. The filling layer FIL may be an organic layer such as acryl resin, epoxy resin, phenolic resin, polyamide resin, or polyimide resin.

The cover layer CVL may be located on the filling layer FIL. The cover layer CVL may be a glass substrate or a polymer resin such as resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin such as resin, it may be directly applied on the filling layer FIL.

The polarizing plate POL may be located on a surface of the cover layer CVL. The polarizing plate POL may be a structure for preventing visibility reduction due to the reflection of external light. The polarizing plate POL may include a linear polarizing plate and a phase retardation film. For example, the phase retardation film may be a quarter-wave plate (λ/4 plate), but aspects of the present specification are not limited to this case. If visibility due to the reflection of external light is sufficiently improved by the first through third color filters CF1 through CF3, the polarizing plate POL may be omitted.

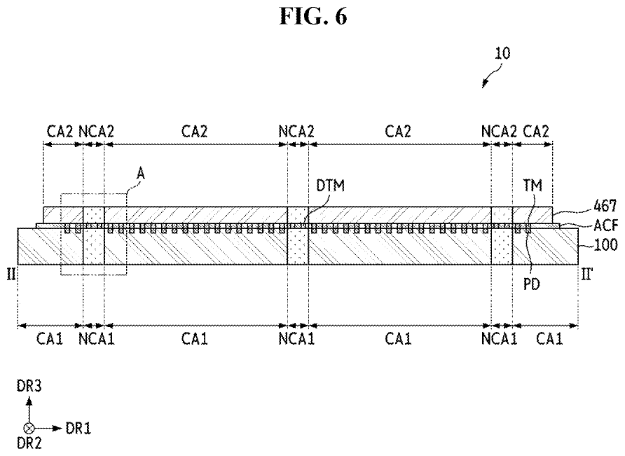

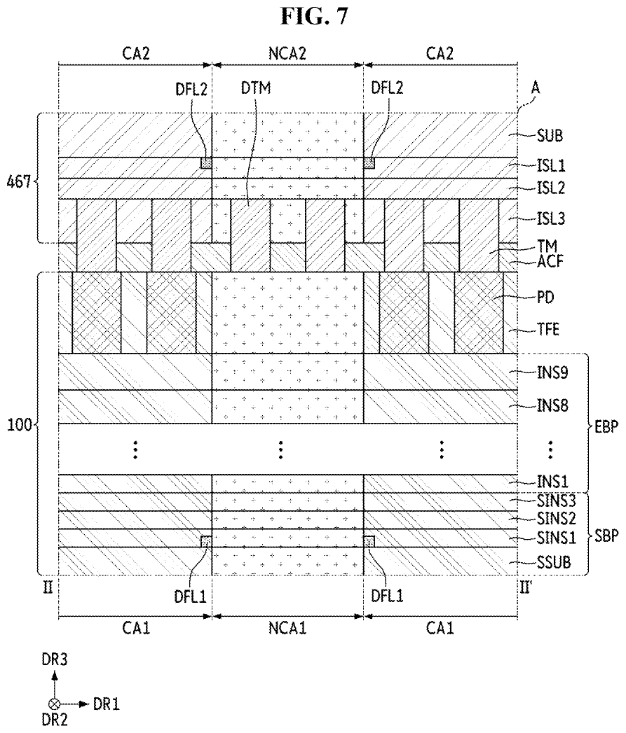

FIG. 6 is a cross-sectional view of an example of the display panel 100, taken along line II-II′ of FIG. 4. For example, FIG. 6 may be a cross-sectional view illustrating the pads PD of the display panel 100 and the display driver 467 overlapping the pads PD. FIG. 7 is an enlarged view of area A of FIG. 6.

As illustrated in FIGS. 6 and 7, the display panel 100 (or the semiconductor substrate SSUB (hereinafter, referred to as a first substrate SSUB) of the display panel 100) may include a first circuit area CA1 (or a first pattern area or a first non-test area) and a first non-circuit area NCA1 (or a first non-pattern area or a first test area).

The first circuit area CA1 and the first non-circuit area NCA1 of the display panel 100 may overlap, for example, the display driver 467.

In the first circuit area CA1 of the display panel 100, first circuit patterns such as the pixel transistors PTR, the conductive layers ML1 through ML8, the via electrodes VA1 through VA10, the reflective electrode layer RL, the first electrodes AND, the light emitting stack layer ES, the second electrode CAT, and various wirings for connecting them may be located. In the first non-circuit area NCA1 of the display panel 100, the first circuit patterns may not be located. In other words, at least one of the first circuit patterns described above and insulating layers (e.g., SINS1, SINS2, INS1-INS9, TFE) may be located in the first circuit area CA1 of the display panel 100, and the insulating layers (e.g., SINS1, SINS2, INS1-INS9, TFE) may be located without the first circuit patterns in the first non-circuit area NCA1 of the display panel 100.

The well areas WA described above may not be located in the first non-circuit area NCA1 of the first substrate SSUB. For example, the well areas WA described above may be located only in the first circuit area CA1 of the first substrate SSUB and may not be located in the first non-circuit area NCA1.

The pads PD may be located in the first circuit area CA1 of the display panel 100. For example, the pads PD may be located on the ninth insulating layer INS9 in the first circuit area CA1. The encapsulation layer TFE may be located between the pads PD. The pads PD may not be located in the first non-circuit area NCA1. In other words, the pads PD of the display panel 100 may be selectively located only in the first circuit area CA1 among the first circuit area CA1 and the first non-circuit area NCA1 of the display panel 100.

A first defining layer DFL1 may be located in the first circuit area CA1 of the display panel 100. The first defining layer DFL1 may define, for example, the first non-circuit area NCA1. The first defining layer DFL1 may be located on the first substrate SSUB. For example, the first defining layer DFL1 may be located close to the first substrate SSUB in the first circuit area CA1. According to an aspect, the first defining layer DFL1 may be located between the first substrate SSUB and the first semiconductor insulating layer SINS1 in the first circuit area CA1. However, aspects of the present specification are not limited to this case, and the first defining layer DFL1 may also be located between adjacent insulating layers of the display panel 100 in the first circuit area CA1. In plan view, the first defining layer DFL1 may be shaped like a closed curve surrounding the first non-circuit area NCA1. In plan view, the first defining layer DFL1 may be located between the first circuit area CA1 and the first non-circuit area NCA1. In plan view, the first defining layer DFL1 may surround dummy terminals DTM. The first defining layer DFL1 may include a material including metal.

As illustrated in FIGS. 6 and 7, the display driver 467 may include a semiconductor substrate SUB (hereinafter, referred to as a second substrate SUB), a plurality of insulating layers ISL1 through ISL3 on the second substrate SUB, a plurality of terminals TM and dummy terminals DTM on a second insulating layer ISL2. Here, the terminals TM and the dummy terminals DTM may be exposed to the outside through contact holes penetrating a third insulating layer ISL3. In addition, a plurality of transistors may be located on the second substrate SUB. The transistors on the second substrate SUB may be electrically connected to the terminals TM through various wirings.

The display driver 467 (or the second substrate SUB of the display driver 467) may include a second circuit area CA2 (or a second pattern area or a second non-test area) and a second non-circuit area NCA2 (or a second non-pattern area or a second test area).

The second circuit area CA2 and the second non-circuit area NCA2 of the display driver 467 may overlap, for example, the display panel 100. For example, the second circuit area CA2 of the display driver 467 may overlap the first circuit area CA1 of the display panel 100, and the second non-circuit area NCA2 of the display driver 467 may overlap the first non-circuit area NCA1 of the display panel 100.

In the second circuit area CA2 of the display driver 467, second circuit patterns such as transistors, conductive layers, via electrodes, and various metal wirings for connecting them may be located. In the second non-circuit area NCA2 of the display driver 467, the second circuit patterns may not be located. In other words, at least one of the second circuit patterns described above and the insulating layers ISL1 through ISL3 may be located in the second circuit area CA2 of the display driver 467, and the insulating layers ISL1 through ISL3 may be located without the second circuit patterns in the second non-circuit area NCA2 of the display driver 467.

Well areas may not be located in the second non-circuit area NCA2 of the second substrate SUB. For example, the well areas described above may be located only in the second circuit area CA2 of the second substrate SUB and may not be located in the second non-circuit area NCA2.

The terminals TM (or pads or bumps) may be located in the second circuit area CA2 of the display driver 467, and the dummy terminals DTM (or dummy pads or dummy bumps) may be located in the second non-circuit area NCA2 of the display driver 467. Here, the terminals TM may be electrically connected to electronic components, and the dummy terminals DTM may not be connected to electronic components. The terminals TM transmit various signals (e.g., data voltages), while the dummy terminals DTM do not transmit any signals. The terminals TM may be connected to the pads PD, respectively. For example, the terminals TM may contact the pads PD, respectively. The pads PD may be larger in size than the terminals TM. For example, in plan view, the area of each of the pads PD may be larger than the area of each of the terminals TM. Each of the terminals TM and the dummy terminals DTM of the display driver 467 may include a material including metal.

A second defining layer DFL2 may be located in the second circuit area CA2 of the display driver 467. The second defining layer DFL2 may define, for example, the second non-circuit area NCA2. The second defining layer DFL2 may be located on the second substrate SUB. For example, the second defining layer DFL2 may be located close to the second substrate SUB in the second circuit area CA2. According to an aspect, the second defining layer DFL2 may be located between the second substrate SUB and the first insulating layer ISL1 in the second circuit area CA2. However, aspects are not limited to this case, and the second defining layer DFL2 may also be located between adjacent insulating layers of the display driver 467 in the second circuit area CA2. In plan view, the second defining layer DFL2 may be located between the second circuit area CA2 and the second non-circuit area NCA2. In plan view, the second defining layer DFL2 may surround the dummy terminals DTM. The second defining layer DFL2 may include a material including metal.

The first defining layer DFL1 and the second defining layer DFL2 may overlap each other. In plan view, a size of the first defining layer DFL1 and a size of the second defining layer DFL2 may be the same. However, aspects are not limited to this case. In plan view, the size of the first defining layer DFL1 and the size of the second defining layer DFL2 may also be different from each other. For example, in plan view, the size of the first defining layer DFL1 may be larger than the size of the second defining layer DFL2.

A conductive adhesive member ACF may be located between the display panel 100 and the display driver 467. For example, the conductive adhesive member ACF may be located between the pads PD of the display panel 100 and the terminals TM of the display driver 467. In addition, the conductive adhesive member ACF may be located between the display panel 100 and the dummy terminals TM of the display driver 467. The pads PD and the terminals TM may be respectively electrically connected to each other by the conductive adhesive member ACF. The conductive adhesive member ACF may include an anisotropic conductive film.

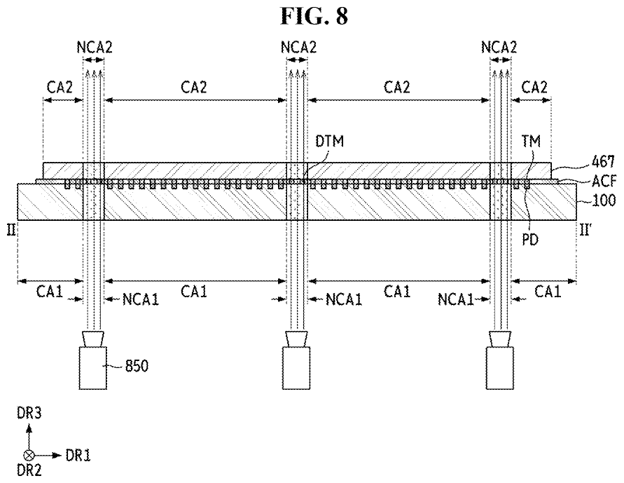

FIG. 8 is a diagram for explaining a method of testing a bonding state between a display panel 100 and a display driver 467 of a display device 10 according to an aspect.

An anisotropic conductive member may include a plurality of conductive particles (e.g., conductive balls). Therefore, pads PD of the display panel 100 and terminals TM of the display driver 467 may be electrically connected to each other by the conductive particles. To check whether the pads PD and the terminals TM are electrically connected, a test process for checking whether the conductive particles are uniformly placed between the pads PD and the terminals TM may be performed. For example, a photographing device 850 may be placed below a back surface of the display panel 100, and dummy terminals DTM may be photographed through the photographing device 850. At this time, the photographing device 850 may be placed below the back surface of the display panel 100 to overlap a first non-circuit area NCA1 of the display panel 100. In other words, the photographing device 850 may photograph the dummy terminals DTM through the first non-circuit area NCA1 and a second non-circuit area NCA2. Since circuit patterns (e.g., various metal patterns) that reflect light are located between the terminals TM and the photographing device 850 in a first circuit area CA1 and a second circuit area CA2, light from the photographing device 850 cannot reach the terminals TM. Accordingly, the terminals TM cannot be photographed through the first circuit area CA1 and the second circuit area CA2. Therefore, the dummy terminals DTM may be photographed through the first non-circuit area NCA1 where no metal is formed. Then, an image analysis of the dummy terminals DTM (e.g., the dummy terminals DTM of the second non-circuit area NCA2) photographed by the photographing device 850 may be performed. As a result of the image analysis, if more than a certain number of pressed shapes made by the conductive particles are observed on the surface of each dummy terminal DTM, it may be determined that the terminals TM and the pads PD are in contact with the conductive particles normally. In this way, the dummy terminals DTM may be be used as an indicator for checking whether there is poor contact between the terminals TM and the pads PD that actually need to be electrically connected.

The photographing device 850 may be, for example, a Short Wavelength InfraRed (SWIR) camera.

According to an aspect, circuit patterns that can reflect light may not be located in the first non-circuit area NCA1 and the second non-circuit area NCA2, and only insulating layers may be located. In other words, circuit patterns (e.g., transistors and various metal wirings) of the first circuit area CA1 are formed while avoiding the first non-circuit area NCA1, and circuit patterns (e.g., transistors and various metal wirings) of the second circuit area CA2 are formed while avoiding the second non-circuit area NCA2. Therefore, insulating layers and the dummy terminals DTM excluding such circuit patterns may be formed in the first non-circuit area NCA1 and the second non-circuit area NCA2. Accordingly, the shapes of the dummy terminals DTM can be accurately photographed through the first non-circuit area NCA1 and the second non-circuit area NCA2.

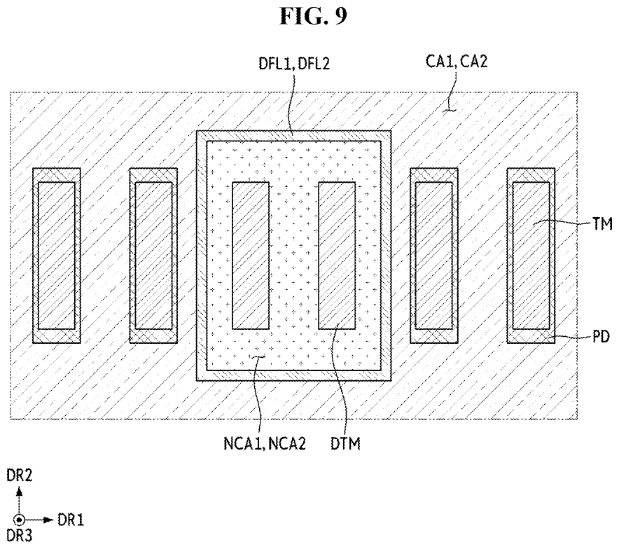

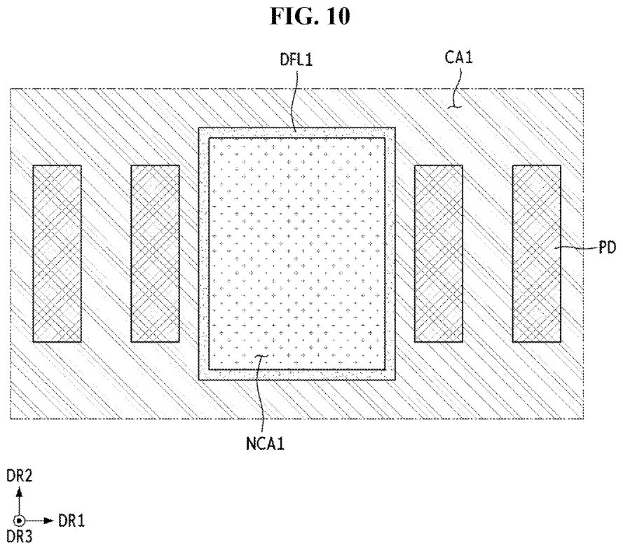

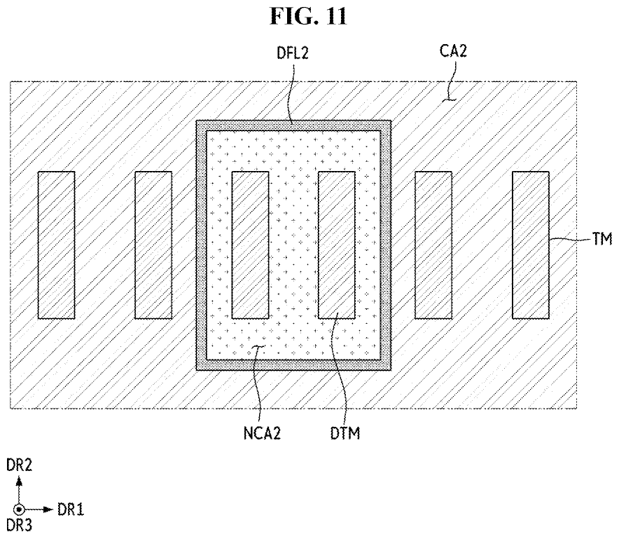

FIG. 9 is a plan view of an overlap area between a display panel 100 and a display driver 467 of a display device 10 according to an aspect. FIG. 10 is a plan view of the display device 10 in a first circuit area CA1 and a first non-circuit area NCA1 of FIG. 9. FIG. 11 is a plan view of the display device 10 in a second circuit area CA2 and a second non-circuit area NCA2 of FIG. 9.

In plan view as in FIGS. 9 through 11, a first defining layer DFL1 may be shaped like a closed curve surrounding the first non-circuit area NCA1, and a second defining layer DFL2 may be shaped like a closed curve surrounding the second non-circuit area NCA2.

In plan view, dummy terminals DTM may be surrounded by the first defining layer DFL1 and the second defining layer DFL2.

In plan view, the first defining layer DFL1 and the second defining layer DFL2 may overlap each other.

In plan view, the area of the first defining layer DFL1 and the area of the second defining layer DFL2 may be equal.

In plan view, pads PD may be larger in size than terminals TM. In addition, in plan view, the pads PD may be larger in size than the dummy terminals DTM. The pads PD and the terminals TM may overlap each other.

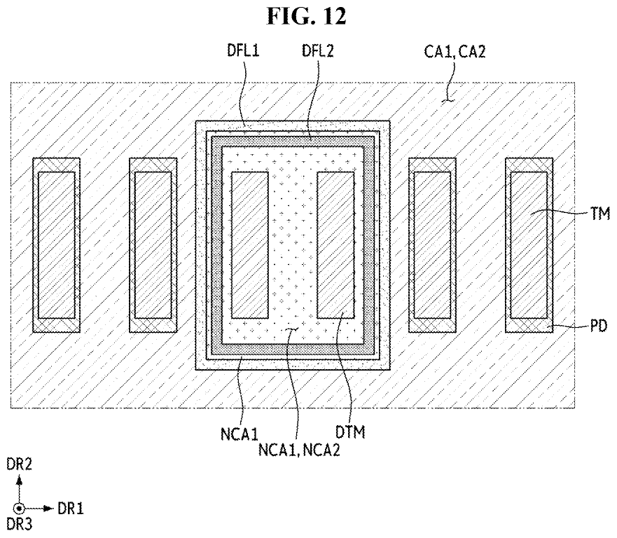

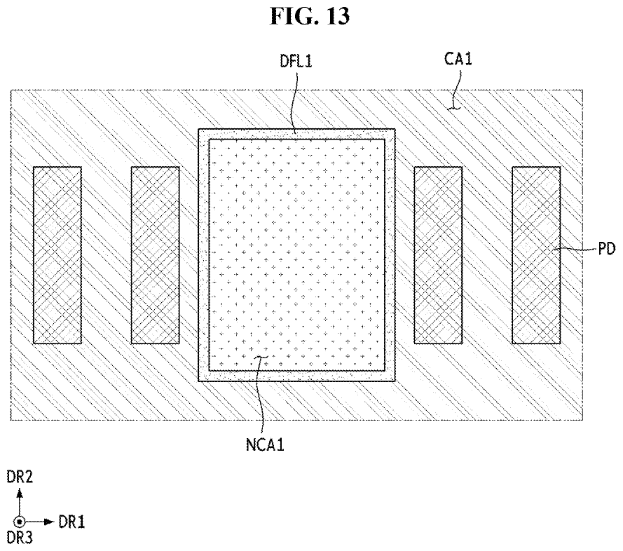

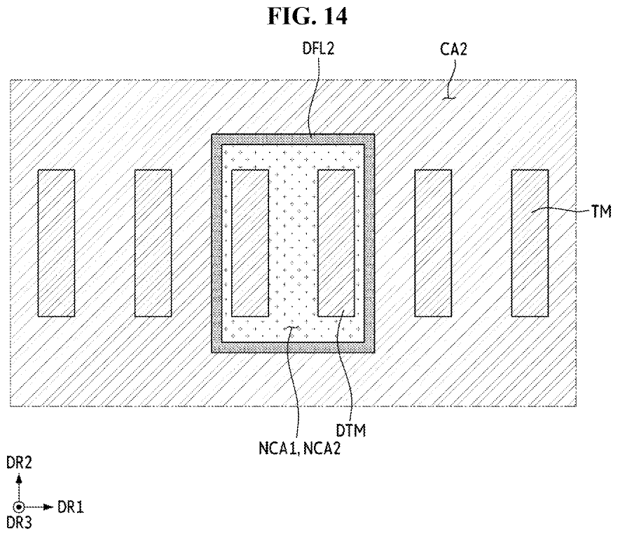

FIG. 12 is a plan view of an overlap area between a display panel 100 and a display driver 467 of a display device 10 according to an aspect. FIG. 13 is a plan view of the display device 10 in a first circuit area CA1 and a first non-circuit area NCA1 of FIG. 12. FIG. 14 is a plan view of the display device 10 in a second circuit area CA2 and a second non-circuit area NCA2 of FIG. 12.

In plan view as in FIGS. 12 through 14, a first defining layer DFL1 may be shaped like a closed curve surrounding the first non-circuit area NCA1, and a second defining layer DFL2 may be shaped like a closed curve surrounding the second non-circuit area NCA2.

In plan view, dummy terminals DTM may be surrounded by the first defining layer DFL1 and the second defining layer DFL2. Here, in plan view, the second defining layer DFL2 may be located between the first defining layer DFL1 and the dummy terminals DTM.

In plan view, the first defining layer DFL1 and the second defining layer DFL2 may not overlap each other.

In plan view, the area of the first defining layer DFL1 and the area of the second defining layer DFL2 may be different from each other. For example, the area of the first defining layer DFL1 may be larger than the area of the second defining layer DFL2. Here, in plan view, the first defining layer DFL1 may surround the second defining layer DFL2. However, aspects are not limited to this case. In plan view, the first defining layer DFL1 and the second defining layer DFL2 may also intersect each other. In this case, the dummy terminals DTM described above may be located in an area surrounded in common by the first defining layer DFL1 and the second defining layer DFL2 (e.g., an intersection area of the first defining layer DFL1 and the second defining layer DFL2.

In plan view, pads PD may be larger in size than terminals TM. In addition, in plan view, the pads PD may be larger in size than the dummy terminals DTM. The pads PD and the terminals TM may overlap each other.

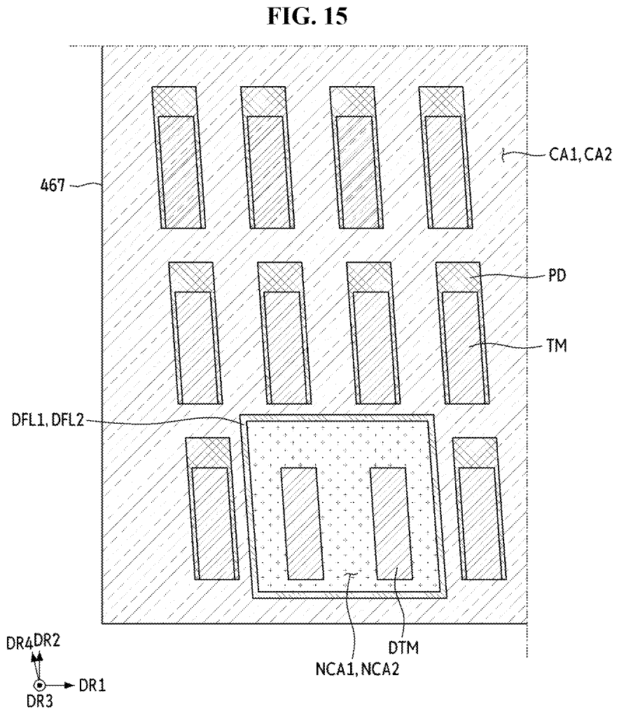

FIG. 15 is a plan view of an overlap area between a display panel 100 and a display driver 467 of a display device 10 according to an aspect.

As illustrated in FIG. 15, pads PD, terminals TM, and dummy terminals DTM may be inclined in a diagonal direction (e.g., a fourth direction DR4). For example, when the display panel 100 and the display driver 467 are bonded together, the pads PD and the terminals TM may be misaligned due to the stretching of the display panel 100 and/or the display driver 467 (e.g., stretching in the first direction DR1). In order to resolve the misalignment due to the stretching, the pads PD, the terminals TM, and the dummy terminals DTM may be inclined in a diagonal direction. For example, when the pads PD and the terminals TM are misaligned due to the stretching, they may be aligned with each other by moving the display driver 467 in a direction (e.g., the second direction DR2) intersecting the stretching direction.

As illustrated in FIG. 15, a first non-circuit area NCA1, a second non-circuit area NCA2, a first defining layer DFL1, and a second defining layer DFL2 may be located at an edge of the display driver 467 (or the display panel 100).

As illustrated in FIG. 15, the first non-circuit area NCA1 may be inclined in a diagonal direction. For example, the first non-circuit area NCA1 may be inclined along the fourth direction DR4.

As illustrated in FIG. 15, the first non-circuit area NCA1 and the second non-circuit area NCA2 may overlap. Also illustrated in FIG. 15, the dummy terminals DTM may be located adjacent to each other in a direction (e.g., the first direction DR1) in which the display driver 467 extends. The dummy terminals DTM adjacent to each other in the first direction DR1 may be located in the second non-circuit area NCA2. The first non-circuit area NCA1 and the second non-circuit area NCA2 may each extend along the first direction DR1.

As illustrated in FIG. 15, the first defining layer DFL1 that defines the first non-circuit area NCA1 may be inclined in a diagonal direction. For example, the first defining layer DFL1 may be inclined along the fourth direction DR4. In addition, the first defining layer DFL1 may extend along the first direction DR1.

In plan view as in FIG. 15, the first defining layer DFL1 and the second defining layer DFL2 may surround the dummy terminals DTM located adjacent to each other in the direction (e.g., the first direction DR1) in which the display driver 467 extends.

As illustrated in FIG. 15, the second non-circuit area NCA2 may have the same shape as the first non-circuit area NCA1 described above.

As illustrated in FIG. 15, the second defining layer DFL2 may have the same shape as the first defining layer DFL1 described above.

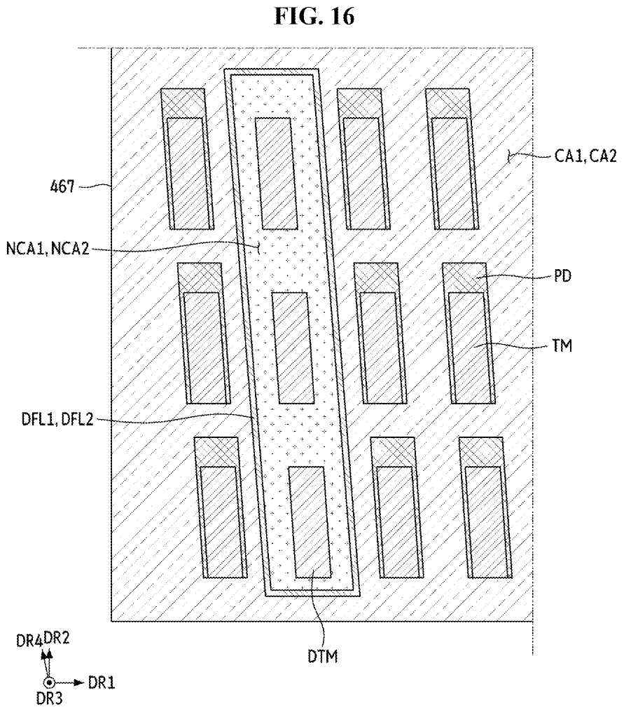

FIG. 16 is a plan view of an overlap area between a display panel 100 and a display driver 467 of a display device 10 according to an aspect.

The display device 10 of FIG. 16 is different from the display device 10 of FIG. 15 described above in the shapes of a first non-circuit area NCA1, a second non-circuit area NCA2, a first defining layer DFL1, and a second defining layer DFL2. This difference is as follows.

As illustrated in FIG. 16, the first non-circuit area NCA1 and the second non-circuit area NCA2 may overlap. Further, dummy terminals DTM are located adjacent to each other in a direction not perpendicular to a direction (e.g., the first direction DR1) in which the display driver 457 extends. The dummy terminals DTM adjacent to each other in the fourth direction DR4 may be located in the second non-circuit area NCA2. The first non-circuit area NCA1 and the second non-circuit area NCA2 may each extend along the fourth direction DR4.

As illustrated in FIG. 16, the dummy terminals DTM are located adjacent to each other along a diagonal direction not perpendicular to the direction (e.g., the first direction DR1) in which the display driver 467 extends. In other words, the dummy terminals DTM are adjacent to each other in the fourth direction DR4. The dummy terminals DTM may be located in the second non-circuit area NCA2.

As illustrated in FIG. 16, the first defining layer DFL1 that defines the first non-circuit area NCA1 may be inclined in a diagonal direction. For example, the first defining layer DFL1 may be inclined along the fourth direction DR4. In addition, the first defining layer DFL1 may extend along the fourth direction DR4.

In plan view as in FIG. 16, the first defining layer DFL1 and the second defining layer DFL2 may surround the dummy terminals DTM located adjacent to each other along a diagonal direction not perpendicular to the direction (e.g., the first direction DR1) in which the display driver 467 extends. For example, the first defining layer DFL1 and the second defining layer DFL2 may surround the dummy terminals DTM located adjacent to each other along the fourth direction DR4.

As illustrated in FIG. 16, the second non-circuit area NCA2 may have the same shape as the first non-circuit area NCA1.

As illustrated in FIG. 16, the second defining layer DFL2 may have the same shape as the first defining layer DFL1.

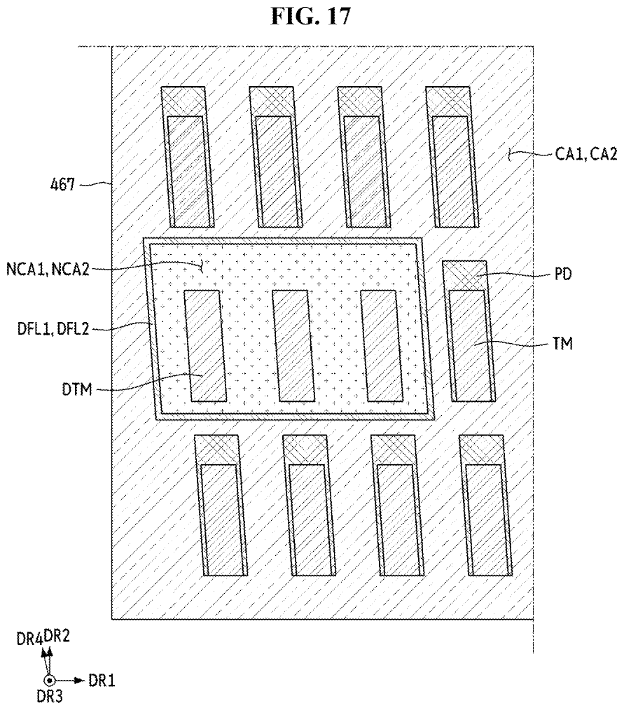

FIG. 17 is a plan view of an overlap area between a display panel 100 and a display driver 467 of a display device 10 according to an aspect.

The display device 10 of FIG. 17 is different from the display device 10 of FIG. 15 described above in the shapes of a first non-circuit area NCA1, a second non-circuit area NCA2, a first defining layer DFL1, and a second defining layer DFL2. This difference is as follows.

As illustrated in FIG. 17, the first non-circuit area NCA1 and the second non-circuit area NCA2 may overlap. Further, FIG. 17 illustrates an outermost dummy terminal DTM among the dummy terminals DTM of the display driver 467. For example, in plan view, the first non-circuit area NCA1 and the second non-circuit area NCA2 may surround at least one dummy terminal DTM located at an outermost position.

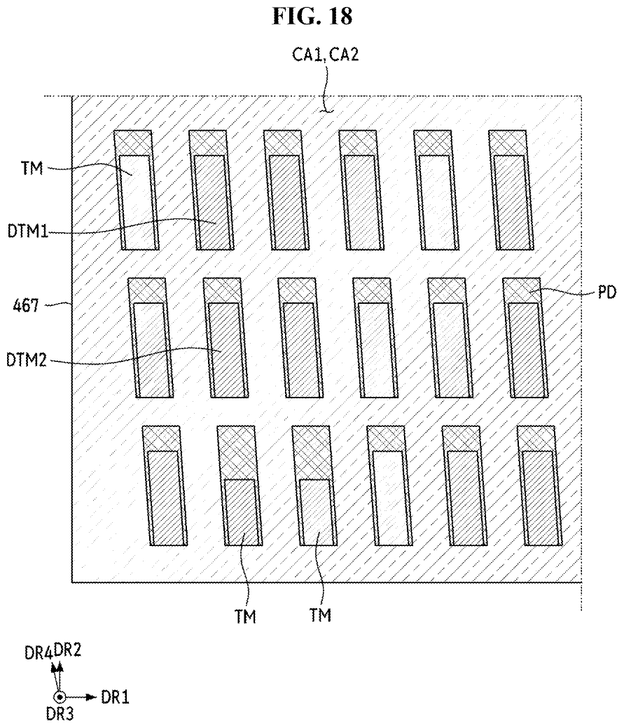

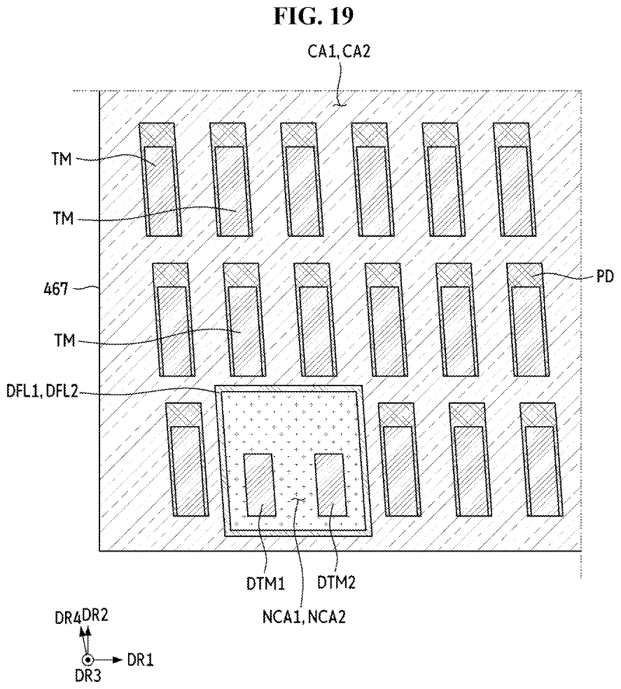

FIGS. 18 and 19 are diagrams for explaining a method of forming a first non-circuit area NCA1 and a second non-circuit area NCA2 by changing a dummy terminal DTM in a display device 10 according to an aspect.

As illustrated in FIG. 18, when a first dummy terminal DTM1 and a second dummy terminal DTM2 are located adjacent to each other in the fourth direction DR4, the first dummy terminal DTM1 and the second dummy terminal DTM2 of FIG. 18 may be changed to terminals TM (e.g., terminals TM for transmitting data voltages) to form the first non-circuit area NCA1 and the second non-circuit area NCA2 at a position illustrated in FIG. 19. Then, as illustrated in FIG. 19, two terminals TM overlapping the first non-circuit area NCA1 and the second non-circuit area NCA2 may be changed to a first dummy terminal DTM1 and a second dummy terminal DTM2, respectively. At this time, pads PD connected to the first dummy terminal DTM1 and the second dummy terminal DTM2 may be removed as illustrated in FIG. 19.

A display device 10 according to an aspect can be applied to various electronic devices. An electronic device according to an aspect includes the display device 10 described above and may further include modules or devices having other additional functions, in addition to the display device 10.

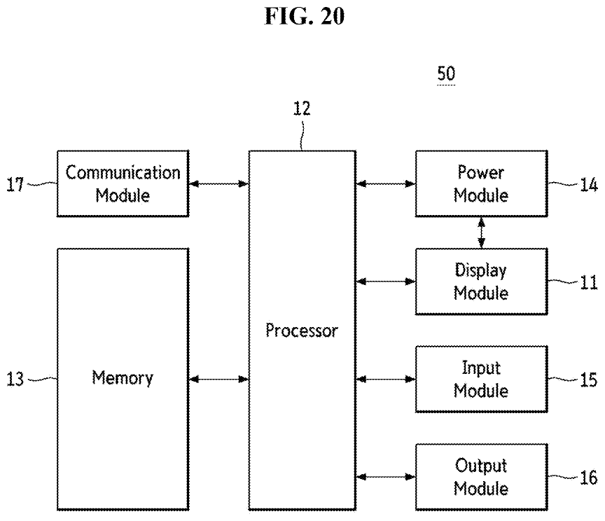

FIG. 20 is a block diagram of an electronic device 50 according to an aspect. Referring to FIG. 20, the electronic device 50 according to the aspect may include a display module 11, a processor 12, a memory 13, and a power module 14. The electronic device 50 may further include an input module 15, a non-image output module 16, and/or a communication module 17.

The electronic device 50 may output various information in the form of images through the display module 11. When the processor 12 executes an application stored in the memory 13, image information provided by the application may be provided to a user through the display module 11. The power module 14 may include a power supply module, such as a power adapter or a battery device, and a power conversion module which generates power necessary for the operation of the electronic device 50 by converting power supplied by the power supply module. The input module 15 may provide input information to the processor 12 and/or the display module 11. The non-image output module 16 may receive non-image information, such as sound, haptic and light, from the processor 12 and provide the information to a user. The communication module 17 is a module that is responsible for transmitting and receiving information between the electronic device 50 and an external device and may include a receiving unit and a transmitting unit.

At least one of the elements of the electronic device 50 described above may be included in a display device according to the aspects described above. In addition, some of individual modules functionally included in one module may be included in the display device, and other modules may be provided separately from the display device. For example, the display device may include the display module 11, and the processor 12, the memory 13 and the power module 14 may be provided not in the display device but in the form of other devices within the electronic device 50.

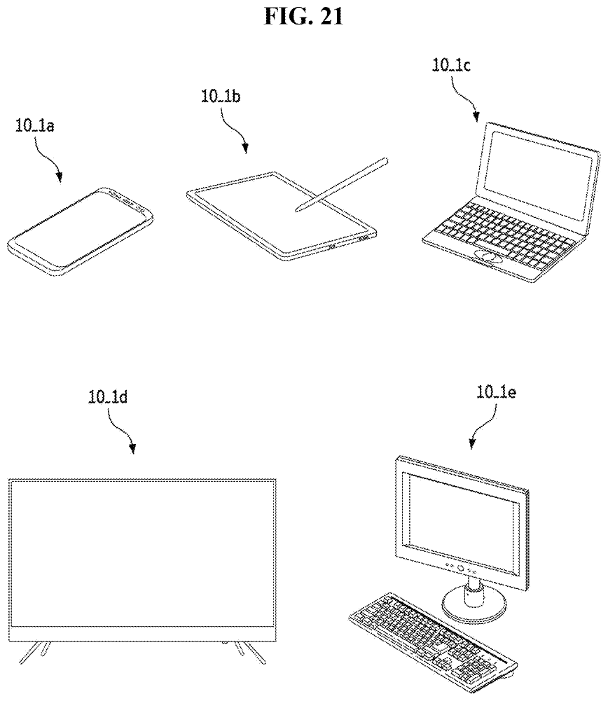

FIGS. 21, 22, and 23 are schematic diagrams of electronic devices according to various aspects. FIGS. 21 through 23 illustrate examples of various electronic devices to which a display device 10 according to aspects is applied.

FIG. 21 illustrates a smartphone 10_1a, a tablet PC 10_1b, a laptop 10_1c, a television 10_1d, and a desk monitor 10_1e as examples of electronic devices.

The smartphone 10_1a may include an input module, such as a touch sensor, and a communication module, in addition to a display module 11. The smartphone 10_1a may process information received through the communication module or other input modules and display the information through a display module of a display device.

Like the smartphone 10_1a, the tablet PC 10_1b, the laptop 10_1c, the television 10_1d, and the desk monitor 10_1e may include a display module and an input module and may further include a communication module in some cases.

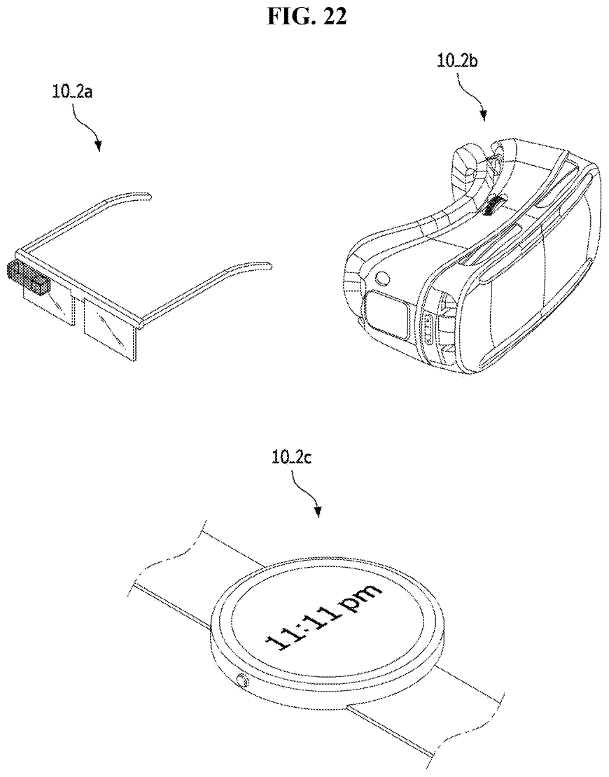

FIG. 22 illustrates a case where an electronic device including a display module is applied to a wearable electronic device. The wearable electronic device may be smart glasses 10_2a, a head-mounted display 10_2b, a smart watch 10_2c, or the like.

The smart glasses 10_2a and the head-mounted display 10_2b may include a display module which outputs a display image and a reflector which provides the output display screen to a user's eyes by reflecting the output display screen. Accordingly, a virtual reality or augmented reality screen can be provided to the user.

The smart watch 10_2c may include a biometric sensor as an input device and may provide biometric information recognized by the biometric sensor to a user through a display module.

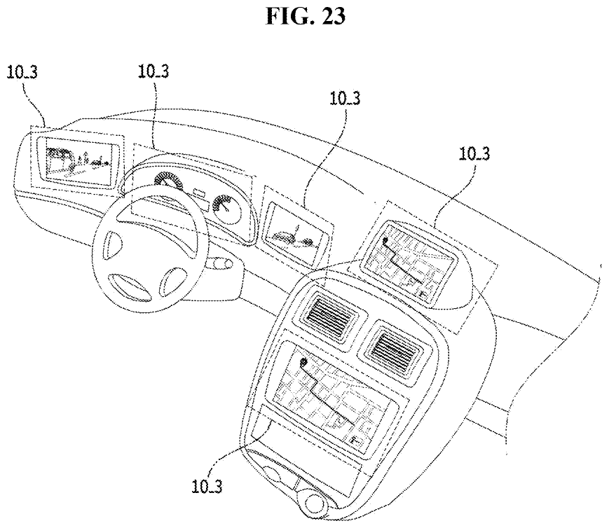

FIG. 23 illustrates a case where an electronic device including a display module is applied to a vehicle. For example, an electronic device 10_3 may be applied to an instrument panel, center fascia, etc. of a vehicle, may be applied to a center information display (CID) located on a dashboard of the vehicle, or may be applied to a room mirror display replacing a side mirror.

In concluding the detailed description, those skilled in the art will appreciate that many variations and modifications can be made to the preferred aspects without substantially departing from the principles of the present disclosure. Therefore, the disclosed preferred aspects of the disclosure are used in a generic and descriptive sense only and not for purposes of limitation.

What is claimed is:

1. A display device comprising:
a display panel comprising a first circuit area and a first non-circuit area;
a pad located in the first circuit area of the display panel;
a display driver connected to the display panel, the display driver comprising a second circuit area and a second non-circuit area;
a terminal located in the second circuit area of the display driver, the terminal connected to the pad; and
a dummy terminal located in the second non-circuit area of the display driver, the dummy terminal overlapping the first non-circuit area.

2. The display device of claim 1, further comprising a first defining layer located in the first circuit area of the display panel to define the first non-circuit area.

3. The display device of claim 2, wherein the first defining layer is a closed curve surrounding the dummy terminal in a plan view.

4. The display device of claim 3, further comprising a second defining layer located in the second circuit area of the display driver to define the second non-circuit area.

5. The display device of claim 4, wherein the second defining layer is a closed curve surrounding the dummy terminal in the plan view.

6. The display device of claim 5, wherein the first defining layer and the second defining layer overlap each other.

7. The display device of claim 6, wherein a size of the first non-circuit area is equal to a size of the second non-circuit area.

8. The display device of claim 5, wherein the first defining layer and the second defining layer do not overlap each other.

9. The display device of claim 8, wherein a size of the first non-circuit area is larger than a size of the second non-circuit area.

10. The display device of claim 9, wherein the first defining layer surrounds the second defining layer in the plan view.

11. The display device of claim 4, wherein each of the first defining layer and the second defining layer comprises a material comprising metal.

12. The display device of claim 1, wherein a circuit pattern comprising a metal material is further located in the first circuit area, and at least one insulating layer is located in the first non-circuit area.

13. The display device of claim 1, wherein a circuit pattern comprising a metal material is further located in the second circuit area, and at least one insulating layer is located in the second non-circuit area.

14. The display device of claim 1, further comprising a conductive adhesive member located between the pad of the display panel and the terminal of the display driver and between the display panel and the dummy terminal of the display driver.

15. The display device of claim 1, wherein the second non-circuit area is located at an edge of the display driver.

16. The display device of claim 1, wherein the first non-circuit area and the second non-circuit area are inclined in a diagonal direction with respect to a direction in which the display driver extends.

17. An electronic device comprising a display device which provides a display screen, wherein the display device comprises:
a display panel comprising a first circuit area and a first non-circuit area;
a pad located in the first circuit area of the display panel;
a display driver connected to the display panel, the display driver comprising a second circuit area and a second non-circuit area;
a terminal located in the second circuit area of the display driver, the terminal connected to the pad; and
a dummy terminal located in the second non-circuit area of the display driver, the dummy terminal overlapping the first non-circuit area.

18. The electronic device of claim 17, further comprising a first defining layer located in the first circuit area of the display panel to define the first non-circuit area.

19. The electronic device of claim 18, wherein the first defining layer is a closed curve surrounding the dummy terminal in a plan view.

20. The electronic device of claim 17, wherein the electronic device is a wearable device comprising a head-mounted display, smart glasses, or a smart watch.
